(19) United States
(12) Patent Application Publication
(10) Pub. No.: US 2026/0107647 A1
(43) Pub. Date: Apr. 16, 2026

(54) DISPLAY DEVICE AND ELECTRONIC DEVICE INCLUDING THE SAME

(71) Applicant: Samsung Display Co., LTD., Yongin-si (KR)

(72) Inventors: YOUNGGU KANG, Yongin-si (KR); JANG WOO KIM, Yongin-si (KR); HYEON-DO PARK, Yongin-si (KR); HYUN-SUNG PARK, Yongin-si (KR); EUNKYUNG YANG, Yongin-si (KR); JUNHO CHOI, Yongin-si (KR)

(21) Appl. No.: 19/058,540

(22) Filed: Feb. 20, 2025

(30) Foreign Application Priority Data
Oct. 10, 2024 (KR) 10-2024-0137492

(51) Int. Cl. H10K 59/126; G06F 3/041; H10K 59/121; H10K 59/124; H10K 59/40

(52) U.S. Cl. CPC H10K 59/126; G06F 3/0412; G06F 3/04164; H10K 59/1213; H10K 59/124; H10K 59/40; G06F 2203/04107

(57) ABSTRACT

A display device includes: a substrate including a display area in which at least one pixel is located, a non-display area adjacent to the display area, and a pad area spaced from one side of the display area; a touch panel in the display area and the non-display area on the substrate; a touch driving pad in the pad area on the substrate, and electrically connected to the touch panel; a demultiplexer circuit in the pad area on the substrate, and located between the touch driving pad and the touch panel in a plan view; a plurality of pad connecting lines on the substrate, and extending from the touch driving pad toward the demultiplexer circuit; and an electrostatic discharge circuit between the plurality of pad connecting lines and the demultiplexer circuit in a plan view.

### CROSS-REFERENCE TO RELATED APPLICATION

The present application claims priority to and the benefit of Korean Patent Application No. 10-2024-0137492, filed on Oct. 10, 2024, in the Korean Intellectual Property Office, the entire disclosure of which is incorporated by reference herein.

### BACKGROUND

### 1. Field

Embodiments of the present disclosure relate to a display device and an electronic device including the same. More particularly, embodiments of the present disclosure relate to the display device that provides a touch function and an electronic device including the same.

### 2. Description of the Related Art

A display device is a device that displays an image that provides visual information. A display device provides a touch function that allows information input by touching a screen, and is being widely applied to various electronic devices such as portable information devices such as smart phones, laptops, monitors, and/or home appliances.

A display device may include pixels that emit light and a driver that transmits signals to the pixels. In addition, a display device may include a demultiplexer (DEMUX) circuit that distributes a data signal or data signal received from the driver.

Each transistor of a demultiplexer circuit may be degraded over time due to electrostatic discharge (ESD) phenomenon caused by stress caused by voltage and current applied by an operation period of the display device and touch operation.

### SUMMARY

Embodiments of the present disclosure provide a display device with improved characteristic of electrostatic discharge.

Embodiments of the present disclosure provide an electronic device including the display device.

According to one or more embodiments, a display device includes: a substrate including a display area in which at least one pixel is located, a non-display area adjacent to the display area, and a pad area spaced from one side of the display area; a touch panel in the display area and the non-display area on the substrate; a touch driving pad in the pad area on the substrate, and electrically connected to the touch panel; a demultiplexer circuit in the pad area on the substrate, and located between the touch driving pad and the touch panel in a plan view; a plurality of pad connecting lines on the substrate, and extending from the touch driving pad toward the demultiplexer circuit; and an electrostatic discharge circuit between the plurality of pad connecting lines and the demultiplexer circuit in a plan view, the electrostatic discharge circuit including: a plurality of electrostatic dissipation patterns spaced from each other in a plan view; and an electrostatic capacitor electrode on the plurality of electrostatic dissipation patterns, and overlapping the plurality of electrostatic dissipation patterns in a plan view.

In one or more embodiments, the electrostatic discharge circuit further includes: a plurality of connecting patterns on the electrostatic capacitor electrode, and electrically connected to the plurality of pad connecting lines.

In one or more embodiments, each of the plurality of connecting patterns overlaps two electrostatic dissipation patterns adjacent to each of the plurality of connecting patterns from among the plurality of the electrostatic dissipation patterns.

In one or more embodiments, the display device further includes: a first insulating structure between the plurality of electrostatic dissipation patterns and the electrostatic capacitor electrode in a cross-sectional view; and a second insulating structure between the electrostatic capacitor electrode and the plurality of the connecting patterns in a cross-sectional view, wherein the plurality of the connecting patterns is electrically connected to the plurality of electrostatic dissipation patterns through at least one contact hole penetrating the first insulating structure and the second insulating structure.

In one or more embodiments, at least one hole exposes an upper surface of each of the plurality of electrostatic dissipation patterns.

In one or more embodiments, a size of the hole is greater than a size of the contact hole.

In one or more embodiments, the contact hole is inside the hole in a plan view.

In one or more embodiments, the pixel includes: at least one transistor on the substrate; and a light-emitting element electrically connected to the transistor and configured to emit light, wherein the transistor includes: an active layer on the substrate; a first gate electrode on the active layer; a second gate electrode on the first gate electrode, and defining a capacitor with the first gate electrode; and a source electrode and a drain electrode on the second gate electrode, and electrically connected to the active layer.

In one or more embodiments, the plurality of the electrostatic dissipation patterns and the first gate electrode are in a same layer, and wherein the electrostatic capacitor electrode and the second gate electrode are in a same layer.

In one or more embodiments, the plurality of connecting patterns, the source electrode, and the drain electrode are in a same layer, and wherein the plurality of pad connecting lines are on the plurality of connecting patterns.

In one or more embodiments, each of the plurality of pad connecting lines extends a first direction, wherein each of the plurality of electrostatic dissipation patterns is spaced from each other in a second direction crossing the first direction in a plan view, and wherein the electrostatic capacitor electrode extends in the second direction, and overlaps each of the plurality of electrostatic dissipation patterns in a plan view.

In one or more embodiments, a length of the electrostatic capacitor electrode in the first direction is greater than a length of the electrostatic capacitor electrode in the second direction.

In one or more embodiments, a length of a portion of the electrostatic capacitor electrode overlapping one electrostatic dissipation pattern from among the plurality of the electrostatic dissipation patterns in the first direction is greater than a length of the portion of the electrostatic capacitor electrode overlapping one electrostatic dissipation pattern from among the plurality of the electrostatic dissipation patterns in the second direction.

In one or more embodiments, the demultiplexer circuit includes: a first demultiplexer circuit adjacent to the electrostatic discharge circuit and including a plurality of first demultiplexer transistors; a second demultiplexer circuit spaced from the first demultiplexer circuit in a plan view, and including a plurality of second demultiplexer transistors; and a third demultiplexer circuit spaced from the second demultiplexer circuit, and including a plurality of third demultiplexer transistors.

In one or more embodiments, a number of the plurality of the second demultiplexer transistors is greater than a number of the plurality of the first demultiplexer transistors, and wherein a number of the plurality of the third demultiplexer transistors is greater than a number of the plurality of the first demultiplexer transistors.

In one or more embodiments, a display device includes: a substrate including a display area in which at least one pixel is located, a non-display area adjacent to the display area, and a pad area spaced from one side of the display area; a touch panel in the display area and the non-display area on the substrate; a touch driving pad in the pad area on the substrate, and electrically connected to the touch panel; a demultiplexer circuit in the pad area on the substrate, located between the touch driving pad and the touch panel in a plan view, and including a first demultiplexer circuit, a second demultiplexer circuit, and a third demultiplexer circuit that are spaced from each other; a plurality of pad connecting lines on the substrate, and extending from the touch driving pad toward the demultiplexer circuit; and an electrostatic discharge circuit including a plurality of resistance patterns located between the plurality of pad connecting lines and the demultiplexer circuit in a plan view, and spaced from each other.

In one or more embodiments, the pixel includes: at least one transistor on the substrate; and a light-emitting element electrically connected to the transistor and configured to emit light, wherein the transistor includes: an active layer on the substrate; a first gate electrode on the active layer; a second gate electrode on the first gate electrode, and defining a capacitor with the first gate electrode; and a source electrode and a drain electrode on the second gate electrode, and electrically connected to the active layer.

In one or more embodiments, the electrostatic discharge circuit further includes: a plurality of connecting patterns electrically connected to the plurality of pad connecting lines, wherein the plurality of resistance patterns and the active layer are in a same layer, wherein the plurality of connecting patterns, the source electrode, and the drain electrode are in a same layer, and wherein the plurality of the pad connecting patterns are on the plurality of connecting patterns.

In one or more embodiments, a resistance of the plurality of resistance patterns is about 15 kΩ to about 25 kΩ.

In one or more embodiments, an electronic device includes: a housing a display device housed in the housing, configured to display an image, and including: a substrate including a display area in which at least one pixel is located, a non-display area adjacent to the display area, and a pad area spaced from one side of the display area; a touch panel in the display area and the non-display area on the substrate; a touch driving pad in the pad area on the substrate, and electrically connected to the touch panel; a demultiplexer circuit in the pad area on the substrate, and located between the touch driving pad and the touch panel in a plan view; a plurality of pad connecting lines on the substrate, and extending from the touch driving pad toward the demultiplexer circuit; and an electrostatic discharge circuit between the plurality of pad connecting lines and the demultiplexer circuit in a plan view, the electrostatic discharge circuit including: a plurality of electrostatic dissipation patterns spaced from each other in a plan view; and an electrostatic capacitor electrode on the plurality of electrostatic dissipation patterns, and overlapping the plurality of electrostatic dissipation patterns in a plan view; and a cover window covering the display device.

In a display device according to embodiments of the present disclosure, an electrostatic discharge circuit may include a plurality of electrostatic dissipation patterns, an electrostatic capacitor electrode overlapping the plurality of electrostatic dissipation patterns in a plan view, and a plurality of connecting patterns electrically connected to the plurality of electrostatic dissipation patterns through contact holes. Accordingly, while the touch panel is driven, charges may be induced through the plurality of electrostatic dissipation patterns, the electrostatic capacitor electrode, and the connecting patterns to control static electricity, so that an electrostatic discharge (ESD) phenomenon generated in the demultiplexer circuit and a peripheral area of the demultiplexer circuit may be prevented. Accordingly, a degradation phenomenon generated in transistors included in the demultiplexer circuit may be prevented without affecting a sensitivity of touch signals transmitted to the touch panel. Accordingly, a touch function of the display device may be improved.

In a display device according to embodiments of the present disclosure, the electrostatic discharge circuit may include a plurality of resistance patterns. Accordingly, while the touch panel is being driven, static electricity flowing into the demultiplexer circuit may be easily blocked through the plurality of resistance patterns, thereby preventing an electrostatic discharge phenomenon generated in the demultiplexer circuit and a peripheral area of the demultiplexer circuit. Accordingly, a degradation phenomenon generated in transistors included in the demultiplexer circuit may be prevented. Accordingly, the touch function of the display device may be improved.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to one or more embodiments of the present disclosure.

FIG. 2 is a block diagram illustrating the display device of FIG. 1.

FIG. 3 is a cross-sectional view illustrating a cross-section taken along the line I-I′ of FIG. 1.

FIG. 4 is a plan view illustrating an enlarged example of an area A of FIG. 1.

FIG. 5 is a plan view illustrating an enlarged example of an area B of FIG. 4.

FIG. 6 is an enlarged plan view illustrating an area C1 of FIG. 5.

FIGS. 7, 8, and 9 are layout diagrams for explaining an arrangement of components included in an electrostatic discharge circuit of FIG. 6.

FIG. 10 is a cross-sectional view illustrating a cross-section taken along the line II-II′ of FIG. 6.

FIG. 11 is a plan view illustrating an enlarged example of an area D1 of FIG. 5.

FIG. 12 is a plan view illustrating an enlarged example of an area D2 of FIG. 5.

FIG. 13 is a plan view illustrating an enlarged example of an area D3 of FIG. 5.

FIG. 14 is a plan view illustrating another enlarged example of the area A of FIG. 1.

FIG. 15 is an enlarged plan view illustrating an area C2 of FIG. 14.

FIGS. 16 and 17 are layout diagrams for explaining an arrangement of components included in an electrostatic discharge circuit of FIG. 15.

FIG. 18 is a cross-sectional view illustrating a cross-section taken along the line III-III′ of FIG. 15.

FIG. 19 is a block diagram illustrating an electronic device according to one or more embodiments of the present disclosure.

FIG. 20 is a view illustrating an example of the electronic device of FIG. 19 implemented as a smartphone

### DETAILED DESCRIPTION

The present disclosure now will be described more fully hereinafter with reference to the accompanying drawings, in which embodiments of the present disclosure are shown. The present disclosure may, however, be embodied in many different forms and should not be construed as limited to the embodiments set forth herein.

Rather, these embodiments are provided so that the present disclosure will be thorough and complete, and will fully convey the scope of the present disclosure to those skilled in the art. Like reference numerals refer to like elements throughout.

It will be understood that, although the terms first, second, third, and/or the like may be used herein to describe various elements, components, areas, layers and/or sections, these elements, components, areas, layers and/or sections should not be limited by these terms. These terms are only used to distinguish one element, component, area, layer or section from another area, layer or section. Thus, a first element, component, area, layer or section discussed below could be termed a second element, component, area, layer, or section without departing from the teachings of the present disclosure.

The terminology used herein is for the purpose of describing particular embodiments only and is not intended to be limiting of the present disclosure. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein may be performed in a suitable order unless otherwise indicated herein or otherwise clearly contradicted by context. The use of any and all examples, or example language (e.g., “such as”), is intended merely to better illustrate the present disclosure and does not pose a limitation on the scope of the present disclosure unless otherwise claimed. No language in the specification should be construed as indicating any non-claimed element as essential to the practice of the present disclosure as used herein.

It will also be understood that when a layer is referred to as being “on” another layer or substrate, it can be directly on the other layer or substrate, or intervening layers may also be present. The same reference numbers indicate the same components throughout the specification.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, a display device and an electronic device including the same in accordance with embodiments of the present disclosure will be described in more detail with reference to the accompanying drawings. The same reference numerals are used for the same components in the drawings, and redundant descriptions of the same components will be omitted.

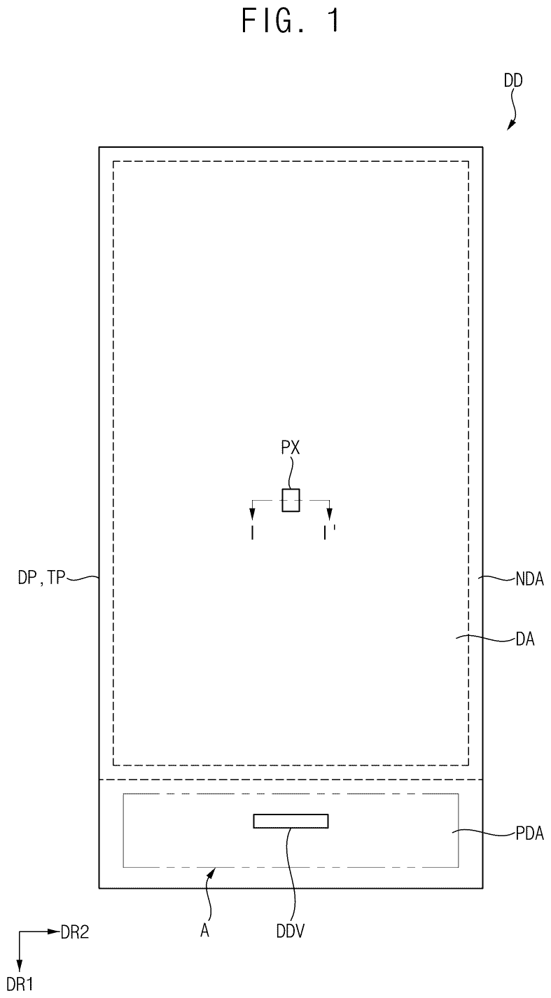

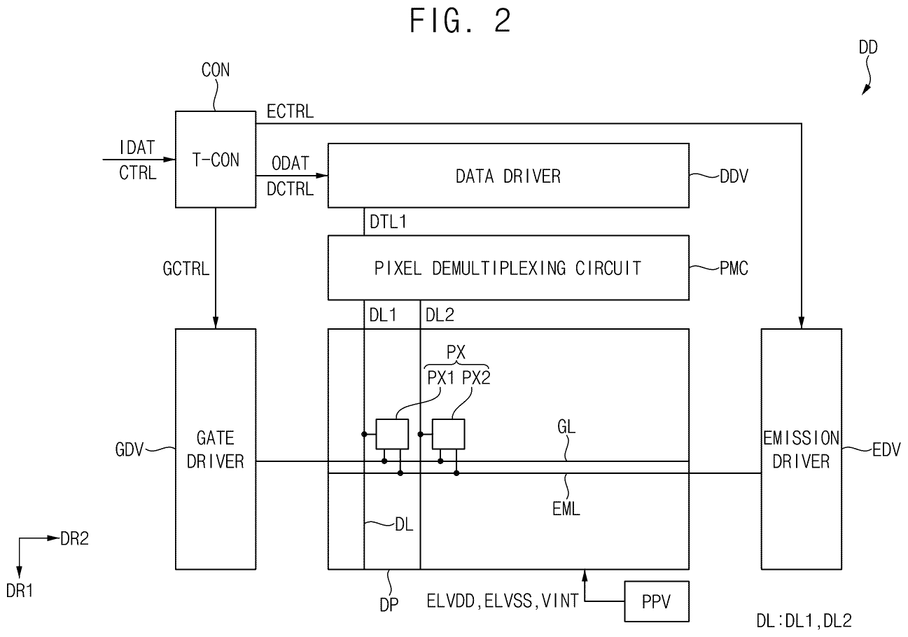

FIG. 1 is a plan view illustrating a display device according to one or more embodiments of the present disclosure. FIG. 2 is a block diagram illustrating the display device of FIG. 1.

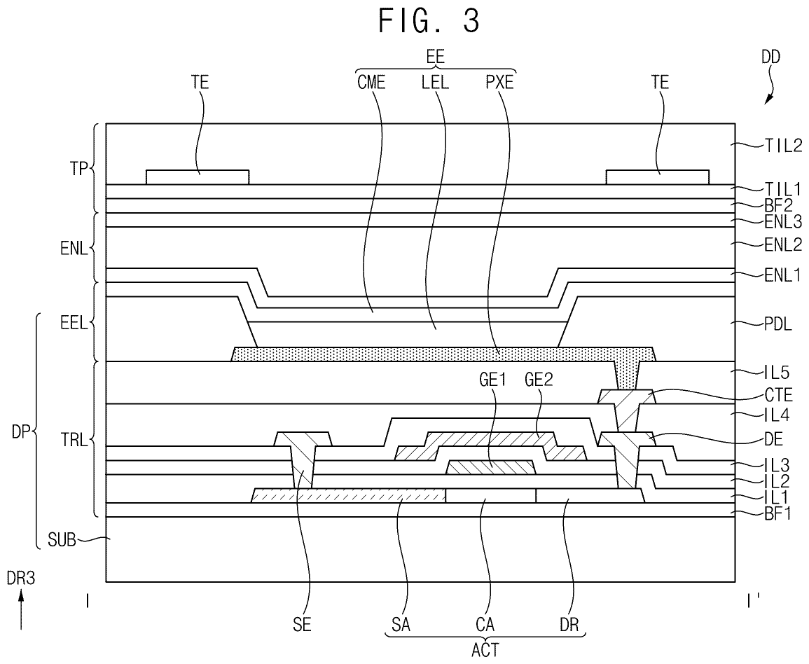

Referring to FIGS. 1 and 2, the display device DD according to one or more embodiments of the present disclosure may include a display area DA, a non-display area NDA around an edge or a periphery of the display area DA, and a pad area PDA. The display device DD may include a display panel DP and a data driver DDV. As the display device DD includes the display panel DP, the display panel DP may also include the display area DA, non-display area NDA, and pad area PDA. In addition, a substrate (e.g., the substrate SUB of FIG. 3) included in the display panel DP may also include the display area DA, non-display area NDA, and pad area PDA.

The display device DD may include a display panel DP and a display panel driver. The display panel driver may include a controller CON, a gate driver GDV, an emission driver EDV, a power supplier PPV, a data driver DDV, and a pixel demultiplexer circuit PMC.

In this specification, a plane may be defined in a first direction DR1 and a second direction DR2, which intersects with the first direction DR1. For example, the first direction DR1 and the second direction DR2 may be perpendicular to each other.

The display area DA may be an area that may generate light or may control the transmittance of light provided from an external light source to display images. At least one pixel PX that emits light may be disposed in the display area DA. A plurality of pixels PX may be disposed in the display area DA. For example, the pixels PX may be disposed in the display area DA in the first direction DR1 and the second direction DR2, forming a matrix.

In one or more embodiments, a pixel PX may include sub-pixels that emit light of different colors. For example, the sub-pixels may include the first to third sub-pixels, the first sub-pixel may emit the first light, the second sub-pixel may emit the second light, and the third sub-pixel may emit the third light. In one or more embodiments, the first light may be red, the second light may be green, and the third light may be blue. However, the colors of light emitted by each sub-pixel included in the pixel PX according to one or more embodiments of the present disclosure may not be limited to thereto and may emit light in various colors, such as magenta, cyan, and yellow.

The non-display area NDA may surround at least a portion of the display area DA. For example, the non-display area NDA may surround the display area DA entirely in a plan view. The non-display area NDA may be defined as an area that does not emit light and does not generate images. The display panel driver for driving the pixels PX may be disposed in the non-display area NDA. The display panel driver may provide signals and/or voltage to the pixels PX. For example, the controller CON, the gate driver GDV, the emission driver EDV, the power supplier PPV, and/or the like may be disposed in the non-display area NDA.

In one or more embodiments, the pixel demultiplexer circuit PMC may be disposed in the non-display area NDA. However, the pixel demultiplexer circuit PMC according to one or more embodiments of the present disclosure may not be necessarily limited this, and the pixel demultiplexer circuit PMC may also be disposed in the pad area PDA.

The pad area PDA may be spaced (e.g., spaced apart) from one side of the display area DA. For example, the pad area PDA may be spaced (e.g., spaced apart) from one side of the display area DA in the first direction DR1. The pad area PDA may be spaced (e.g., spaced apart) from the display area DA in the first direction DR1 with the non-display area NDA in between. That is, the non-display area NDA may be disposed between the pad area PDA and the display area DA. The data driver DDV that applies data signals to the pixels PX may be disposed in the pad area PDA.

Each of the plurality of gate lines GL may extend in the second direction DR2. Each of the plurality of gate lines GL may be spaced (e.g., spaced apart) from each other in the first direction DR1. Each of the plurality of data lines DL may extend in the first direction DR1, and each of the plurality of data lines DL may be spaced (e.g., spaced apart) from each other in the second direction DR2. Each of the plurality of emission lines EML may extend in the second direction DR2, and each of the plurality of emission lines EML may be spaced (e.g., spaced apart) from each other in the first direction DR1.

In one or more embodiments, the data lines DL may include the first data line DL1 and the second data line DL2. In addition, the pixels PX may include the first pixel PX1 and the second pixel PX2. In one or more embodiments, each of the plurality of pixels PX may be electrically connected to each of the gate lines GL, data lines DL, and emission lines EML.

For example, one gate line of the gate lines GL may be electrically connected to each of the first pixel PX1 and the second pixel PX2, and the emission lines EML may be electrically connected to each of the first pixel PX1 and the second pixel PX2. The first data line DL1 may be electrically connected to the first pixel PX1, and the second data line DL2 may be electrically connected to the second pixel PX2.

The controller CON may receive input image data IDAT and input control signals CTRL from an external device (e.g., a host processor such as a graphic processing unit, GPU). In one or more embodiments, the input image data IDAT may include red image data, green image data, and blue image data.

In one or more embodiments, the input image data IDAT may further include white image data. In one or more embodiments, the input image data IDAT may include magenta image data, yellow image data, and/or cyan image data. The input control signals CTRL may include a master clock signal and a data enable signal. The input control signals CTRL may further include a vertical sync signal and a horizontal sync signal.

The controller CON may generate a gate control signal GCTRL, a data control signal DCTRL, an emission control signal ECTRL, and an output data signal ODAT based on the input image data IDAT and the input control signals CTRL.

The controller CON may generate a gate control signal GCTRL for controlling the operation of the gate driver GDV based on the input control signals CTRL. The controller CON may output the gate control signal GCTRL to the gate driver GDV. The gate control signal GCTRL may include a vertical start signal and a gate clock signal.

The controller CON may generate an emission control signal ECTRL for controlling the operation of the emission driver EDV based on the input control signals CTRL. The controller CON may output the emission control signal ECTRL to the emission driver EDV.

The controller CON may generate a data control signal DCTRL for controlling the operation of the data driver DDV based on the input control signals CTRL. The controller CON may output the data control signal DCTRL to the data driver DDV. The data control signal DCTRL may include a horizontal start signal and a load signal.

The controller CON may generate the output data signal ODAT based on the input image data IDAT. The controller CON may output the output data signal ODAT to the data driver DDV.

The gate driver GDV may output signals to the plurality of gate lines GL for driving the pixels PX based on the gate control signals GCTRL received from the controller CON.

The emission driver EDV may generate an emission drive signal EM based on the emission control signals ECTRL. The emission drive signal EM may include a gate-on voltage and a gate-off voltage. The emission drive signal EM may include a vertical start signal, a clock signal, and/or the like.

The voltage supplier PPV may provide a constant voltage to the pixels PX. For example, the constant voltage may include an initialization voltage VINT, a high power voltage ELVDD, a low power voltage ELVSS, and/or the like.

The data driver DDV may receive the data control signal DCTRL and the output data signal ODAT from the controller CON. In one or more embodiments, the data driver DDV may receive a gamma reference voltage from a gamma reference voltage generator. The data driver DDV may convert the output data signal ODAT into an analog form of data voltage using the gamma reference voltage. The data driver DDV may output the data voltage to each of the data lines DL.

The pixel demultiplexer circuit PMC may deliver the data voltage to the pixels PX. In one or more embodiments, the pixel demultiplexer circuit PMC may deliver the data voltage in a time-divided manner. For example, the pixel demultiplexer circuit PMC may receive the first data voltage and the second data voltage. The pixel demultiplexer circuit PMC may sequentially deliver the first data voltage and the second data voltage to the first data line DL1 and the second data line DL2.

FIG. 3 is a cross-sectional view illustrating a cross-section taken along the line I-I′ of FIG. 1.

Referring to FIG. 3, the display device DD may include a display panel DP, an encapsulation layer ENL, and a touch panel TP. The display panel DP may include a substrate SUB, a transistor layer TRL, and a light-emitting element layer EEL.

The transistor layer TRL may include a first buffer layer BF1, an active layer ACT, a first insulating layer IL1, a first gate electrode GE1, a second insulating layer IL2, a second gate electrode GE2, a third insulating layer IL3, a source electrode SE, a drain electrode DE, a fourth insulating layer IL4, a contact electrode CTE, and a fifth insulating layer IL5. The light-emitting element layer EEL may include a pixel electrode PXE, a pixel defining layer PDL, a light-emitting layer LEL, and a common electrode CME. The encapsulation layer ENL may include a first encapsulation layer ENL1, a second encapsulation layer ENL2, and a third encapsulation layer ENL3. The touch panel TP may include a second buffer layer BF2, a first touch insulating layer TIL1, a touch electrode TE, and a second touch insulating layer TIL2.

The active layer ACT, first gate electrode GE1, source electrode SE, and drain electrode DE may define at least one transistor. The pixel defining layer PDL, light-emitting layer EEL, and common electrode CME may define a light-emitting element EE.

The pixel, (e.g., the pixel PX in FIG. 1), may include the at least one transistor and a light-emitting element EE. In one or more embodiments, the light-emitting element EE and the at least one transistor may be electrically connected.

In this specification, a third direction DR3 may be perpendicular to the plane defined by the first direction DR1 and the second direction DR2 of FIG. 1. For example, the display panel DP, encapsulation layer ENL, and the touch panel TP may be sequentially stacked along the third direction DR3.

The substrate SUB may serve as the base of the display panel DP. The substrate SUB may be formed from transparent or opaque materials, such as glass, quartz, and/or plastic. For example, the plastic may include polyimide, polyethylene naphthalate, polyethylene terephthalate, polycarbonate, polyetherimide, polyethersulfone, and/or the like. These may be used alone or in combination with each other.

The first buffer layer BF1 may be disposed on the substrate SUB. The first buffer layer BF1 may prevent the diffusion of metal atoms or impurities from the substrate SUB into the active layer ACT. In addition, the first buffer layer BF1 may control a rate of heat transfer during the crystallization process for forming the active layer ACT.

The active layer ACT may be disposed on the first buffer layer BF1. The active layer ACT may include amorphous silicon, polycrystalline silicon, and/or oxide semiconductors. The active layer ACT may include a source area SA, a drain area DR, and a channel area CA disposed between the source and drain areas.

The first insulating layer IL1 may be disposed on the active layer ACT and the first buffer layer BF1. The first insulating layer IL1 may cover the active layer ACT on the first buffer layer BF1. For example, the first insulating layer IL1 may have a substantially uniform thickness following the profile of the active layer ACT. However, the first insulating layer IL1 according to the present disclosure may not be limited to this, and the first insulating layer IL1 may sufficiently cover the active layer ACT and have a substantially flat upper surface without creating a step around the active layer ACT.

In one or more embodiments, the first insulating layer IL1 may include inorganic insulating materials. The inorganic insulating materials may include silicon nitride (SiNₓ), silicon oxide (SiOₓ), silicon oxynitride (SiOₓN_{y}), and/or the like. These may be used alone or in combination.

The first gate electrode GE1 may be disposed on the first insulating layer IL1. The first gate electrode GE1 may overlap with the channel area CA of the active layer ACT in the third direction DR3 (e.g., a thickness direction) and may include metal, alloy, conductive metal oxide, conductive metal nitride, and/or transparent conductive material. These materials may be used alone or in combination.

The second insulating layer IL2 may be disposed on the first gate electrode GE1 and the first insulating layer IL1. The second insulating layer IL2 may cover the first gate electrode GE1 on the first insulating layer IL1. For example, the second insulating layer IL2 may have a substantially uniform thickness following the profile of the first gate electrode GE1. However, the second insulating layer IL2 according to one or more embodiments of the present disclosure may not be limited to this, and the second insulating layer IL2 may sufficiently cover the first gate electrode GE1 and have a substantially flat upper surface without creating a step around the first gate electrode GE1.

In one or more embodiments, the second insulating layer IL2 may include inorganic insulating materials. The inorganic insulating materials may include silicon nitride, silicon oxide, or silicon oxynitride, and/or the like. These may be used alone or in combination with each other.

The second gate electrode GE2 may be disposed on the second insulating layer IL2 overlapping the first gate electrode GE1. In one or more embodiments, the second gate electrode GE2 may overlap the first gate electrode GE1 in a plan view (e.g., in the third direction DR3 (e.g., a thickness direction of the substrate SUB)), thus defining a capacitor together with the first gate electrode GE1. However, the second gate electrode GE2 according to one or more embodiments of the present disclosure may not be limited to this.

The third insulating layer IL3 may be disposed on the second gate electrode GE2 and the second insulating layer IL2. The third insulating layer IL3 may cover the second gate electrode GE2 on the second insulating layer IL2. For example, the third insulating layer IL3 may have a substantially uniform thickness following the profile of the second gate electrode GE2. However, the third insulating layer IL3 according to one or more embodiments of the present disclosure may not be limited to this, and the third insulating layer IL3 may sufficiently cover the second gate electrode GE2 and have a substantially flat upper surface without creating a step around the second gate electrode GE2.

In one or more embodiments, the third insulating layer IL3 may include inorganic insulating materials. The inorganic insulating materials may include silicon nitride, silicon oxide, or silicon oxynitride, and/or the like. These may be used alone or in combination.

The source electrode SE and drain electrode DE may be disposed on the third insulating layer IL3. In one or more embodiments, the source electrode SE and drain electrode DE may contact the active layer ACT through contact holes that penetrate the first insulating layer IL1, second insulating layer IL2, and third insulating layer IL3 in a thickness direction (e.g., the third direction DR3). For example, the source electrode SE may contact the source area SA through the contact hole, and the drain electrode DE may contact the drain area DR through the contact hole.

In one or more embodiments, the source electrode SE and drain electrode DE may include metal, alloy, conductive metal oxide, conductive metal nitride, and/or transparent conductive material, and/or the like. These materials may be used alone or in combination with each other.

The fourth insulating layer IL4 may be disposed on the third insulating layer IL3 covering the source electrode SE and drain electrode DE. For example, the fourth insulating layer IL4 may cover the source electrode SE and drain electrode DE on the third insulating layer IL3. In one or more embodiments, a hole exposing an upper surface of the drain electrode DE may be defined in the fourth insulating layer IL4. However, the fourth insulating layer IL4 according to one or more embodiments of the present disclosure may not be limited to this. For example, the hole defined in the fourth insulating layer IL4 may also expose the upper surface of the source electrode SE.

In one or more embodiments, the fourth insulating layer IL4 may have a substantially flat upper surface. In one or more embodiments, the fourth insulating layer IL4 may include organic insulating materials, such as acrylic resin, epoxy resin, polyimide, or polyethylene, and/or the like. These may be used alone or in combination with each other.

The contact electrode CTE may be disposed on the fourth insulating layer IL4 and may contact the drain electrode DE through the hole defined in the fourth insulating layer IL4. However, the contact electrode CTE according to one or more embodiments of the present disclosure may not be limited to this. For example, the contact electrode CTE may also contact the source electrode SE. In one or more embodiments, the contact electrode CTE may include metal, alloy, conductive metal oxide, conductive metal nitride, and/or transparent conductive material, and these may be used alone or in combination.

The fifth insulating layer IL5 may be disposed on the fourth insulating layer IL4 covering the contact electrode CTE. For example, the fifth insulating layer IL5 may cover the contact electrode CTE on the fourth insulating layer IL4. In one or more embodiments, a hole exposing the upper surface of the contact electrode CTE may be defined in the fifth insulating layer IL5.

In one or more embodiments, the fifth insulating layer IL5 may have a substantially flat upper surface and may include organic insulating materials, such as acrylic resin, epoxy resin, polyimide, and/or polyethylene, and the like. These may be used alone or in combination with each other.

The pixel electrode PXE may be disposed on the fifth insulating layer IL5. In one or more embodiments, the pixel electrode PXE may contact the contact electrode CTE through the hole defined in the fifth insulating layer IL5. The pixel electrode PXE may include metal, alloy, conductive metal oxide, conductive metal nitride, or transparent conductive material. For example, the pixel electrode PXE may include silver (Ag) and/or indium tin oxide (ITO), and/or the like. These may be used alone or in combination with each other.

The pixel defining layer PDL may be disposed on the fifth insulating layer IL5 and may partially cover the pixel electrode PXE. In addition, a hole exposing at least portion of the pixel electrode PXE may be defined in the pixel defining layer PDL. For example, the hole defined in the pixel defining layer PDL may expose a central portion of the pixel electrode PXE while covering an edge of the pixel electrode PXE. In one or more embodiments, the pixel defining layer PDL may include organic insulating materials, such as polyimide.

The light-emitting layer LEL may be disposed on the pixel electrode PXE. For example, the light-emitting layer LEL may be disposed in the hole defined in the pixel defining layer PDL. In one or more embodiments, the light-emitting layer LEL may include a light-emitting material. For example, the light-emitting material may include a low-molecular organic compound or a high-molecular organic compound. However, the present disclosure may not be limited this, and the light-emitting layer LEL may include a material such as a quantum dot.

The common electrode CME may be disposed on the light-emitting layer LEL. The common electrode CME may cover the light-emitting layer LEL and the pixel defining layer (PDL). In one or more embodiments, the common electrode CME may include a metal, an alloy, a conductive metal oxide, a conductive metal nitride, a transparent conductive material, and/or the like. For example, the common electrode CME may include aluminum (Al), platinum (Pt), silver, magnesium (Mg), gold (Au), chromium (Cr), tungsten (W), titanium (Ti), and/or the like. These may be used alone or in combination with each other.

The first encapsulation layer ENL1 may be disposed on the common electrode CME. The first encapsulation layer ENL1 may cover the light-emitting element (EE). The first encapsulation layer ENL1 may have a substantially uniform thickness along the profile of the common electrode CME. In one or more embodiments, the first encapsulating layer ENL1 may include an inorganic insulating material. For example, the inorganic insulating material may include silicon nitride, silicon oxide, silicon oxynitride, and/or the like. These may be used alone or in combination with each other.

The second encapsulating layer ENL2 may be disposed on the first encapsulating layer ENL1. The second encapsulating layer ENL2 may have a substantially flat upper surface without forming a step around the first encapsulating layer ENL1. In one or more embodiments, the second encapsulating layer ENL2 may include an organic insulating material. For example, the organic insulating material may include an acrylic resin, an epoxy resin, a polyimide, polyethylene, and/or the like. These may be used alone or in combination with each other.

The third encapsulating layer ENL3 may be disposed on the second encapsulating layer ENL2. The third encapsulating layer ENL3 may have a substantially uniform thickness and a substantially flat upper surface. In one or more embodiments, the third encapsulating layer ENL3 may include an inorganic insulating material. For example, the inorganic insulating material may include silicon nitride, silicon oxide, silicon oxynitride, and/or the like. These may be used alone or in combination with each other. The encapsulating layer ENL may seal the display area of the display panel DP (e.g., the display area DA of FIG. 1) to protect the light-emitting element EE from external impurities.

The second buffer layer BF2 may be disposed on the third encapsulating layer ENL3. In one or more embodiments, the second buffer layer BF2 may include an inorganic insulating material and/or an organic insulating material. However, the second buffer layer BF2 according to one or more embodiments of the present disclosure may not be necessarily limited this, and the second buffer layer BF2 may not be disposed on the third encapsulating layer ENL3.

The first touch insulating layer TIL1 may be disposed on the second buffer layer BF2. The first touch insulating layer TIL1 may cover the second buffer layer BF2. In one or more embodiments, the first touch insulating layer TIL1 may include an inorganic insulating material and/or an organic insulating material.

The touch electrode TE may be disposed on the first touch insulating layer TIL1. The touch electrode TE may include a metal oxide, a conductive metal nitride, a transparent conductive material, and/or the like. For example, the touch electrode TE may include aluminum, copper (Cu), titanium, molybdenum (Mo), indium tin oxide, and/or the like. These may be used alone or in combination with each other. In one or more embodiments, the touch electrode TE may have a single-layer structure. However, the touch electrode TE according to one or more embodiments of the present disclosure may not be necessarily limited this, and the touch electrode TE may have a multi-layer structure.

The second touch insulating layer TIL2 may be disposed on the touch electrode TE and the first touch insulating layer TIL1. The second touch insulating layer TIL2 may cover the touch electrode TE. In one or more embodiments, the second touch insulating layer TIL2 may include an inorganic insulating material and/or an organic insulating material.

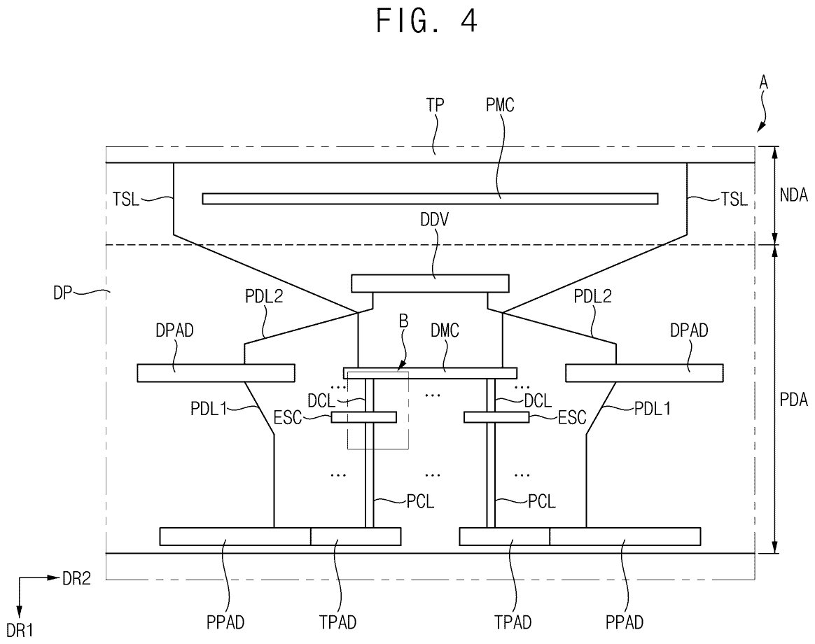

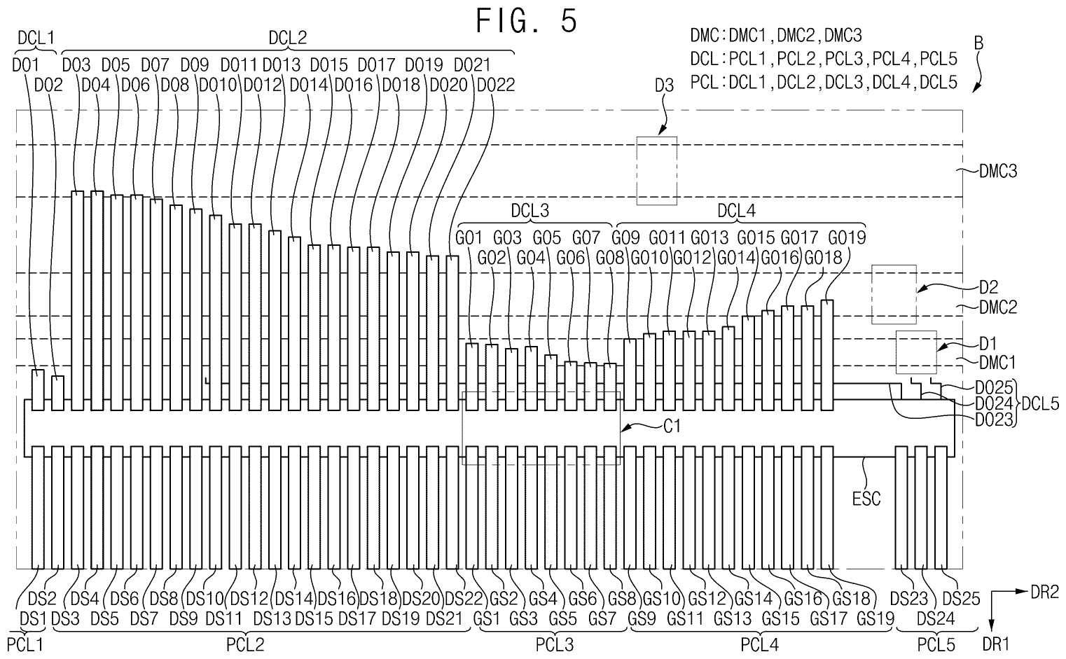

FIG. 4 is a plan view illustrating an enlarged example of an area A of FIG. 1. FIG. 5 is a plan view illustrating an enlarged example of an area B of FIG. 4.

Referring to FIGS. 4 and 5, the display panel DP may include a display panel driving pad PPAD, a touch driving pad TPAD, a data driving pad DPAD, a demultiplexer circuit DMC, a plurality of pad connecting lines PCL, a plurality of touch signal lines TSL, a plurality of demultiplexer connecting lines DCL, and an electrostatic discharge circuit ESC.

The display panel driving pad PPAD may generate signals for driving the display panel DP. In one or more embodiments, the display panel driving pad PPAD may be electrically connected to the display panel DP.

The touch driving pad TPAD may generate signals for driving the touch panel TP. In one or more embodiments, the touch driving pad TPAD may be electrically connected to the touch panel TP.

In one or more embodiments, the touch panel TP may be disposed in the display area (e.g., the display area DA of FIG. 1) and the non-display area NDA. However, an arrangement of the touch panel TP according to one or more embodiments of the present disclosure may not be necessarily limited this, and the touch panel TP may also be disposed in the pad area PDA.

In one or more embodiments, the display panel driving pad PPAD and the touch driving pad TPAD may be formed integrally. However, the display panel driving pad PPAD and the touch driving pad TPAD according to one or more embodiments of the present disclosure may not be necessarily limited to this.

The data driving pad DPAD may be disposed in an opposite direction from the display panel driving pad PPAD in the first direction DR1. The data driving pad DPAD may be electrically connected to the display panel driving pad PPAD through the first pad signal line PDL1. For example, the first pad signal line PDL1 may extend from the display panel driving pad PPAD toward the data driving pad DPAD.

The data driving pad DPAD may be electrically connected to the data driver DDV through the second pad signal line PDL2. For example, the second pad signal line PDL2 may extend from the data driving pad DPAD toward the data driver DDV.

A plurality of pad connecting lines PCL may electrically connect the touch driving pad TPAD and the demultiplexer circuit DMC. In one or more embodiments, each of the plurality of pad connecting lines PCL may extend from the pad area PDA on the substrate (e.g., the substrate SUB of FIG. 3) toward the demultiplexer circuit DMC. In one or more embodiments, each of the plurality of pad connecting lines PCL may be electrically connected to an end facing the first direction DR1 of the electrostatic discharge circuit ESC. For example, each of the plurality of pad connecting lines PCL may contact the end facing the first direction DR1 of the electrostatic discharge circuit ESC.

The demultiplexer circuit DMC may transmit a signal for driving the touch panel TP to the touch panel TP through a plurality of pad connecting lines PCL and demultiplexer connecting lines DCL from the touch driving pad TPAD. For example, the demultiplexer circuit DMC may be electrically connected to the touch panel TP through the plurality of touch signal lines TSL.

The demultiplexer circuit DMC may divide signals applied to each of the plurality of pad connecting lines PCL extended from the touch driving pad TPAD and transmit signals to the touch panel TP. In one or more embodiments, a number of the plurality of touch signal lines TSL may be greater than the number of a plurality of pad connecting lines PCL.

The demultiplexer circuit DMC may include a first demultiplexer circuit DMC1, a second demultiplexer circuit DMC2, and a third demultiplexer circuit DMC3. The first demultiplexer circuit DMC1 may be adjacent to the electrostatic discharge circuit ESC. For example, the first demultiplexer circuit DMC1 may be disposed in an opposite direction from the electrostatic discharge circuit ESC in the first direction DR1. The second demultiplexer circuit DMC2 may be disposed between the electrostatic discharge circuit ESC and the third demultiplexer circuit DMC3 in a plan view. The first demultiplexer circuit DMC1 may be disposed between the electrostatic discharge circuit ESC and the second demultiplexer circuit DMC2 in a plan view. The third demultiplexer circuit DMC3 may be adjacent to the second demultiplexer circuit DMC2.

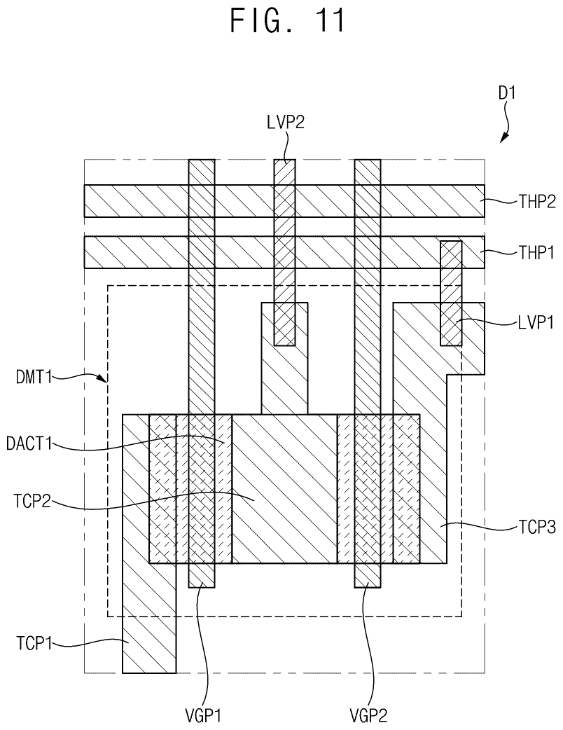

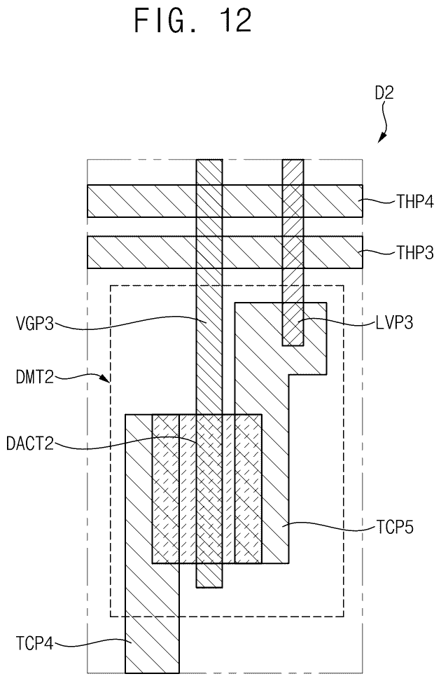

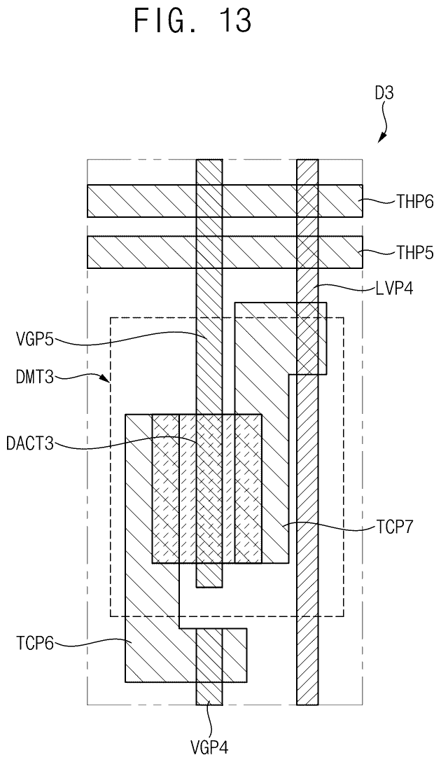

The first demultiplexer circuit DMC1 may include a first demultiplexer transistor (e.g., the first demultiplexer transistor DMT1 of FIG. 11). The second demultiplexer circuit DMC2 may include a second demultiplexer transistor (e.g., the second demultiplexer transistor DMT2 of FIG. 12). The third demultiplexer circuit DMC3 may include a third demultiplexer transistor (e.g., the first demultiplexer transistor DMT3 of FIG. 13). In one or more embodiments of the second demultiplexer circuit DMC2 and the third demultiplexer circuit DMC3, each of the first demultiplexer circuit DMC1, the second demultiplexer circuit DMC2, and the third demultiplexer circuit DMC3 may be spaced (e.g., spaced apart) from each other in a plan view.

The plurality of pad connecting lines PCL may include a plurality of first pad connecting lines PCL1, a plurality of second pad connecting lines PCL2, a plurality of third pad connecting lines PCL3, a plurality of fourth pad connecting lines PCL4, and a plurality of fifth pad connecting lines PCL5.

The plurality of first pad connecting lines PCL1 may include a first data signal line DS1 and a second data signal line DS2. However, the number of signal lines included in the first pad connecting lines PCL1 according to one or more embodiments of the present disclosure may not be necessarily limited this.

A first touch signal for transmission to the first demultiplexer circuit DMC1 may be applied to the plurality of first pad connecting lines PCL1. For example, the first touch signal may be applied to each of the first data signal line DS1 and the second data signal line DS2. The first touch signal may be a signal for driving the touch panel TP.

In one or more embodiments, the second demultiplexer circuit DMC2 may be electrically connected to the first demultiplexer circuit DMC1. For example, the first demultiplexer circuit DMC1 may divide the first touch signal transmitted from the plurality of first pad connecting lines PCL1 and transmit the first touch signal to the second demultiplexer circuit DMC2.

In one or more embodiments, the first data signal line DS1 and the second data signal line DS2 may be spaced (e.g., spaced apart) from each other in a plan view. In one or more embodiments, the plurality of first pad connecting lines PCL1 may be arranged along the second direction DR2 in an order of the first data signal line DS1 and the second data signal line DS2 at a constant interval from each other.

In one or more embodiments, the first data signal line DS1 and the second data signal line DS2 may extend from the touch driving pad TPAD in a direction opposite to the first direction DR1. In one or more embodiments, lengths of the first data signal line DS1 and the second data signal line DS2 in the first direction DR1 may be substantially a same. However, a length relationship of each of the signal lines included in the first pad connecting lines PCL1 according to one or more embodiments of the present disclosure in the first direction DR1 may not be necessarily limited this.

The plurality of second pad connecting lines PCL2 may include a third data signal line DS3, a fourth data signal line DS4, a fifth data signal line DS5, a sixth data signal line DS6, a seventh data signal line DS7, an eighth data signal line DS8, a ninth data signal line DS9, a tenth data signal line DS10, an eleventh data signal line DS11, a twelfth data signal line DS12, a thirteenth data signal line DS13, a fourteenth data signal line DS14, a fifteenth data signal line DS15, a sixteenth data signal line DS16, a seventeenth data signal line DS17, an eighteenth data signal line DS18, a nineteenth data signal line DS19, a twentieth data signal line DS20, a twenty-first data signal line DS21, and a twenty-second data signal line DS22. However, a number of signal lines included in the second pad connecting lines PCL2 according to one or more embodiments of the present disclosure may not be necessarily limited this.

A second touch signal for transmission to the third demultiplexer circuit DMC3 may be applied to a plurality of second pad connecting lines PCL2. For example, the second touch signal may be applied to each of the third, fourth, fifth, sixth, seventh, eighth, ninth, tenth, eleventh, twelfth, thirteenth, fourteenth, fifteenth, sixteenth, seventeenth, eighteenth, nineteenth, twentieth, twenty-first, and twenty-second data signal lines DS3, DS4, DS5, DS6, DS7, DS8, DS9, DS10, DS11, DS12, DS13, DS14, DS15, DS16, DS17, DS18, DS19, DS20, DS21, and DS22. The second touch signal may be a signal for driving the touch panel TP.

In one or more embodiments, each of the third, fourth, fifth, sixth, seventh, eighth, ninth, tenth, eleventh, twelfth, thirteenth, fourteenth, fifteenth, sixteenth, seventeenth, eighteenth, nineteenth, twentieth, twenty-first, and twenty-second data signal lines DS3, DS4, DS5, DS6, DS7, DS8, DS9, DS10, DS11, DS12, DS13, DS14, DS15, DS16, DS17, DS18, DS19, DS20, DS21, and DS22 may be spaced (e.g., spaced apart) from each other in a plan view. The plurality of second pad connecting lines PCL2 may be arranged along the second direction DR2 at regular intervals from each other in an order of the third data signal line DS3, the fourth data signal line DS4, the fifth data signal line DS5, the sixth data signal line DS6, the seventh data signal line DS7, the eighth data signal line DS8, the ninth data signal line DS9, the tenth data signal line DS10, the eleventh data signal line DS11, the twelfth data signal line DS12, the thirteenth data signal line DS13, the fourteenth data signal line DS14, the fifteenth data signal line DS15, the sixteenth data signal line DS16, the seventeenth data signal line DS17, the eighteenth data signal line DS18, the nineteenth data signal line DS19, the twentieth data signal line DS20, the twenty-first data signal line DS21, and the twenty-second data signal line DS22.

In one or more embodiments, the third, fourth, fifth, sixth, seventh, eighth, ninth, tenth, eleventh, twelfth, thirteenth, fourteenth, fifteenth, sixteenth, seventeenth, eighteenth, nineteenth, twentieth, twenty-first, and twenty-second data signal lines DS3, DS4, DS5, DS6, DS7, DS8, DS9, DS10, DS11, DS12, DS13, DS14, DS15, DS16, DS17, DS18, DS19, DS20, DS21, and DS22 may extend in a direction opposite to the first direction DR1 from the touch driving pad TPAD

In one or more embodiments, a length of each of the third, fourth, fifth, sixth, seventh, eighth, ninth, tenth, eleventh, twelfth, thirteenth, fourteenth, fifteenth, sixteenth, seventeenth, eighteenth, nineteenth, twentieth, twenty-first, and twenty-second data signal lines DS3, DS4, DS5, DS6, DS7, DS8, DS9, DS10, DS11, DS12, DS13, DS14, DS15, DS16, DS17, DS18, DS19, DS20, DS21, and DS22 in the first direction DR1 may be substantially a same. However, a length relationship of each of the signal lines included in the second pad connecting lines PCL2 according to one or more embodiments of the present disclosure in the first direction DR1 may not be necessarily limited this.

The plurality of third pad connecting lines PCL3 may include a first gate signal line GS1, a second gate signal line GS2, a third gate signal line GS3, a fourth gate signal line GS4, a fifth gate signal line GS5, a sixth gate signal line GS6, a seventh gate signal line GS7, and an eighth gate signal line GS8. However, a number of signal lines included in the third pad connecting lines PCL3 according to the embodiments of the present disclosure may not be necessarily limited this.

The plurality of third pad connecting lines PCL3 may be applied with a first gate signal for turning on the first demultiplexer transistor included in the first demultiplexer circuit DMC1. For example, the first gate signal may be applied to each of the first, second, third, fourth, fifth, sixth, seventh, and eighth gate signal lines GS1, GS2, GS3, GS4, GS5, GS6, GS7, and GS8.

In one or more embodiments, the first, second, third, fourth, fifth, sixth, seventh, and eighth gate signal lines GS1, GS2, GS3, GS4, GS5, GS6, GS7, and GS8 may be spaced (e.g., spaced apart) from each other in a plan view. In one or more embodiments, the plurality of third pad connecting lines PCL3 may be arranged in an order of the first gate signal line GS1, the second gate signal line GS2, the third gate signal line GS3, the fourth gate signal line GS4, the fifth gate signal line GS5, the sixth gate signal line GS6, the seventh gate signal line GS7, and the eighth gate signal line GS8 along the second direction DR2 at a constant interval from each other.

In one or more embodiments, the first, second, third, fourth, fifth, sixth, seventh, and eighth gate signal lines GS1, GS2, GS3, GS4, GS5, GS6, GS7, and GS8 may extend in a direction opposite to the first direction DR1 from the touch driving pad TPAD.

In one or more embodiments, a length of each of the first second, third, fourth, fifth, sixth, seventh, and eighth gate signal lines GS1, GS2, GS3, GS4, GS5, GS6, GS7, and GS8 in the first direction DR1) may be substantially a same. However, a length relationship of each of the signal lines included in the third pad connecting lines PCL3 according to one or more embodiments of the present disclosure in the first direction DR1 may not be necessarily limited this.

The plurality of fourth pad connecting lines PCL4 may include a ninth gate signal line GS9, a tenth gate signal line GS10, an eleventh gate signal line GS11, a twelfth gate signal line GS12, a thirteenth gate signal line GS13, a fourteenth gate signal line GS14, a fifteenth gate signal line GS15, a sixteenth gate signal line GS16, a seventeenth gate signal line GS17, an eighteenth gate signal line GS18, and a nineteenth gate signal line GS19. However, a number of signal lines included in the fourth pad connecting lines PCL4 according to one or more embodiments of the present disclosure may not be necessarily limited this.

The plurality of fourth pad connecting lines PCL4 may be applied with a second gate signal for turning on the second demultiplexer transistor included in the second demultiplexer circuit DMC2. For example, the second gate signal may be applied to each of the ninth, tenth, eleventh, twelfth, thirteenth, fourteenth, fifteenth, sixteenth, seventeenth, eighteenth, and nineteenth gate signal lines GS9, GS10, GS11, GS12, GS13, GS14, GS15, GS16, GS17, GS18, and GS19.

In one or more embodiments, the ninth, tenth, eleventh, twelfth, thirteenth, fourteenth, fifteenth, sixteenth, seventeenth, eighteenth, and nineteenth gate signal lines GS9, GS10, GS11, GS12, GS13, GS14, GS15, GS16, GS17, GS18, and GS19 may be spaced (e.g., spaced apart) from each other in a plan view. In one or more embodiments, a plurality of fourth pad connecting lines PCL4 may be arranged in an order of a ninth gate signal line GS9, a tenth gate signal line GS10, an eleventh gate signal line GS11, a twelfth gate signal line GS12, a thirteenth gate signal line GS13, a fourteenth gate signal line GS14, a fifteenth gate signal line GS15, a sixteenth gate signal line GS16, a seventeenth gate signal line GS17, an eighteenth gate signal line GS18, and a nineteenth gate signal line GS19 along the second direction DR2 at a constant interval from each other.

In one or more embodiments, the ninth, tenth, eleventh, twelfth, thirteenth, fourteenth, fifteenth, sixteenth, seventeenth, eighteenth, and nineteenth gate signal lines GS9, GS10, GS11, GS12, GS13, GS14, GS15, GS16, GS17, GS18, and GS19 may extend in a direction opposite to the first direction DR1 from the touch driving pad TPAD.

In one or more embodiments, a length of each of the ninth, tenth, eleventh, twelfth, thirteenth, fourteenth, fifteenth, sixteenth, seventeenth, eighteenth, and nineteenth gate signal lines GS9, GS10, GS11, GS12, GS13, GS14, GS15, GS16, GS17, GS18, and GS19 in the first direction DR1 may be substantially a same. However, a length relationship of each of the signal lines included in the fourth pad connecting lines PCL4 according to one or more embodiments of the present disclosure in the first direction DR1 may not be necessarily limited this.

A plurality of fifth pad connecting lines PCL5 may include a twenty-third data signal line DS23, a twenty-fourth data signal line DS24, and a twenty-fifth data signal line DS25. However, a number of signal lines included in the fifth pad connecting lines PCL5 according to one or more embodiments of the present disclosure may not be necessarily limited this.

A third touch signal for transmission to a third demultiplexer circuit DMC3 may be applied to a plurality of fifth pad connecting lines PCL5. For example, the third touch signal may be applied to each of the twenty-third data signal line DS23, the twenty-fourth data signal line DS24, and the twenty-fifth data signal line DS25. The third touch signal may be a signal for driving a touch panel TP.

In one or more embodiments, each of the twenty-third data signal line DS23, the twenty-fourth data signal line DS24, and the twenty-fifth data signal line DS25 may be spaced (e.g., spaced apart) from each other in a plan view. In one or more embodiments, the plurality of fifth pad connecting lines PCL5 may be arranged along the second direction DR2 in an order of the twenty-third data signal line DS23, the twenty-fourth data signal line DS24, and the twenty-fifth data signal line DS25 at a constant interval from each other.

In one or more embodiments, the twenty-third data signal line DS23, the twenty-fourth data signal line DS24, and the twenty-fifth data signal line DS25 may extend in the opposite direction of the first direction DR1 from the touch driving pad TPAD. In one or more embodiments, a length of each of the twenty-third data signal line DS23, the twenty-fourth data signal line DS24, and the twenty-fifth data signal line DS25 in the first direction DR1 may be substantially the same. However, a length relationship of each of the signal lines included in the fifth pad connecting lines PCL5 according to one or more embodiments of the present disclosure in the first direction DR1 may not be necessarily limited this.

The plurality of demultiplexer connecting lines DCL may include a first demultiplexer connecting lines DCL1, a second demultiplexer connecting lines DCL2, a third demultiplexer connecting lines DCL3, a fourth demultiplexer connecting lines DCL4, and a fifth demultiplexer connecting lines DCL5.

In one or more embodiments, a plurality of demultiplexer connecting lines DCL may correspond to a plurality of pad connecting lines PCL. For example, the first demultiplexer connecting lines DCL1 may correspond to the first pad connecting line PCL1. Specifically, a same signal may be applied to the first demultiplexer connecting lines DCL1 and the first pad connecting line PCL1, and the first demultiplexer connecting lines DCL1 and the first pad connecting line PCL1 may be electrically connected to each other by an electrostatic discharge circuit ESC.

For example, the second demultiplexer connecting lines DCL2 may correspond to the second pad connecting lines PCL2. Specifically, the second demultiplexer connecting lines DCL2 and the second pad connecting lines PCL2 may be electrically connected to each other by an electrostatic discharge circuit ESC.

For example, the third demultiplexer connecting lines DCL3 may correspond to the third pad connecting lines PCL3. Specifically, the third demultiplexer connecting lines DCL3 and the third pad connecting lines PCL3 may be electrically connected to each other by an electrostatic discharge circuit ESC.

For example, the fourth demultiplexer connecting lines DCL4 may correspond to the fourth pad connecting lines PCL4. Specifically, the fourth demultiplexer connecting lines DCL4 and the fourth pad connecting lines PCL4 may be applied with a same signal, and the fourth demultiplexer connecting lines DCL4 and the first pad connecting line PCL4 may be electrically connected to each other by an electrostatic discharge circuit ESC.

For example, the fifth demultiplexer connecting lines DCL5 may correspond to the fifth pad connecting line PCL5. Specifically, the fifth demultiplexer connecting lines DCL5 and the fifth pad connecting line PCL5 may be applied with a same signal, and the fifth demultiplexer connecting lines DCL5 and the fifth pad connecting line PCL5 may be electrically connected to each other by an electrostatic discharge circuit ESC.

The plurality of first demultiplexer connecting lines DCL1 may include a first data output signal line DO1 and a second data output signal line DO2. However, a number of signal lines included in the first demultiplexer connecting lines DCL1 according to one or more embodiments of the present disclosure may not be necessarily limited this.

The plurality of first demultiplexer connecting lines DCL1 may transmit the first touch signal received from the first pad connecting lines PCL1 to the touch panel TP. For example, each of the first data output signal line DO1 and the second data output signal line DO2 may transmit the first touch signal to the touch panel TP.

In one or more embodiments, each of the first data output signal line DO1 and the second data output signal line DO2 may be spaced (e.g., spaced apart) from each other in a plan view. In one or more embodiments, a plurality of first demultiplexer connecting lines DCL1 may be arranged along the second direction DR2 in an order of the first data output signal line DO1 and the second data output signal line DO2 at a constant interval from each other.

In one or more embodiments, the first data output signal line DO1 and the second data output signal line DO2 may extend from the electrostatic discharge circuit ESC in an opposite direction to the first direction DR1. In one or more embodiments, the lengths of the first data output signal line DO1 and the second data output signal line DO2 in the first direction DR1 may be different from each other. In one or more other embodiments, a length of the first data output signal line DO1 and the second data output signal line DO2 in the first direction DR1 may be substantially the same. However, the length relationship of each of the signal lines included in the first demultiplexer connecting lines DCL1 according to one or more embodiments of the present disclosure in the first direction DR1 or the second direction DR2 may not be necessarily limited this.

The plurality of second demultiplexer connecting lines DCL2 may include a third data output signal line DO3, a fourth data output signal line DO4, a fifth data output signal line DO5, a sixth data output signal line DO6, a seventh data output signal line DO7, an eighth data output signal line DO8, a ninth data output signal line DO9, a tenth data output signal line DO10, an eleventh data output signal line DO11, a twelfth data output signal line DO12, a thirteenth data output signal line DO13, a fourteenth data output signal line DO14, a fifteenth data output signal line DO15, a sixteenth data output signal line DO16, a seventeenth data output signal line DO17, an eighteenth data output signal line DO18, a nineteenth data output signal line DO19, a twentieth data output signal line DO20, a twenty-first data output signal line DO21, and a twenty-second data output signal line DO22. However, a number of signal lines included in the second demultiplexer connecting lines DCL2 according to one or more embodiments of the present disclosure may not be necessarily limited this.

A plurality of second demultiplexer connecting lines DCL2 may transmit the second touch signal received from the second pad connecting lines PCL2 to the touch panel TP. For example, each of the third, fourth, fifth, sixth, seventh, eighth, ninth, tenth, eleventh, twelfth, thirteenth, fourteenth, fifteenth, sixteenth, seventeenth, eighteenth, nineteenth, twentieth, twenty-first, and twenty-second data output signal lines DO3, DO4, DO5, DO6, DO7, DO8, DO9, DO10, DO11, DO12, DO13, DO14, DO15, DO16, DO17, DO18, DO19, DO20, DO21, and DO22 may transmit the second touch signal to the touch panel TP.

In one or more embodiments, each of the third, fourth, fifth, sixth, seventh, eighth, ninth, tenth, eleventh, twelfth, thirteenth, fourteenth, fifteenth, sixteenth, seventeenth, eighteenth, nineteenth, twentieth, twenty-first, and twenty-second data output signal lines DO3, DO4, DO5, DO6, DO7, DO8, DO9, DO10, DO11, DO12, DO13, DO14, DO15, DO16, DO17, DO18, DO19, DO20, DO21, and DO22 may be spaced (e.g., spaced apart) from each other in a plan view. The plurality of second demultiplexer connecting lines DCL2 are arranged in the second direction DR2 at regular intervals and arranged in an order of the third data output signal line DO3, the fourth data output signal line DO4, the fifth data output signal line DO5, the sixth data output signal line DO6, the seventh data output signal line DO7, the eighth data output signal line DO8, the ninth data output signal line DO9, the tenth data output signal line DO10, the eleventh data output signal line DO11, the twelfth data output signal line DO12, the thirteenth data output signal line DO13, the fourteenth data output signal line DO14, the fifteenth data output signal line DO15, the sixteenth data output signal line DO16, the seventeenth data output signal line DO17, the eighteenth data output signal line DO18, the nineteenth data output signal line DO19, the twentieth data output signal line DO20, the twenty-first data output signal line DO21, and the twenty-second data output signal line DO22.

In one or more embodiments, the third, fourth, fifth, sixth, seventh, eighth, ninth, tenth, eleventh, twelfth, thirteenth, fourteenth, fifteenth, sixteenth, seventeenth, eighteenth, nineteenth, twentieth, twenty-first, and twenty-second data output signal lines DO3, DO4, DO5, DO6, DO7, DO8, DO9, DO10, DO11, DO12, DO13, DO14, DO15, DO16, DO17, DO18, DO19, DO20, DO21, and DO22 may extend from the electrostatic discharge circuit ESC in the opposite direction to the first direction DR1.

In one or more embodiments, lengths of at least two of the third, fourth, fifth, sixth, seventh, eighth, ninth, tenth, eleventh, twelfth, thirteenth, fourteenth, fifteenth, sixteenth, seventeenth, eighteenth, nineteenth, twentieth, twenty-first, and twenty-second data output signal lines DO3, DO4, DO5, DO6, DO7, DO8, DO9, DO10, DO11, DO12, DO13, DO14, DO15, DO16, DO17, DO18, DO19, DO20, DO21, and DO22 in the first direction DR1 may be different from each other. In one or more other embodiments, lengths of each of the third, fourth, fifth, sixth, seventh, eighth, ninth, tenth, eleventh, twelfth, thirteenth, fourteenth, fifteenth, sixteenth, seventeenth, eighteenth, nineteenth, twentieth, twenty-first, and twenty-second data output signal lines DO3, DO4, DO5, DO6, DO7, DO8, DO9, DO10, DO11, DO12, DO13, DO14, DO15, DO16, DO17, DO18, DO19, DO20, DO21, and DO22 in the first direction DR1 may be substantially a same. However, a length relationship of each of the signal lines included in the second demultiplexer connecting lines DCL2 according to one or more embodiments of the present disclosure in the first direction DR1 or the second direction DR2 may not be necessarily limited this.

The plurality of third demultiplexer connecting lines DCL3 may include a first gate output signal line GO1, a second gate output signal line GO2, a third gate output signal line GO3, a fourth gate output signal line GO4, a fifth gate output signal line GO5, a sixth gate output signal line GO6, a seventh gate output signal line GO7, and an eighth gate output signal line GO8. However, a number of signal lines included in the third demultiplexer connecting lines DCL3 according to one or more embodiments of the present disclosure may not be necessarily limited this.

The plurality of third demultiplexer connecting lines DCL3 may transmit the first gate signal received from the third pad connecting lines PCL3 to the first demultiplexer circuit DMC1. For example, each of the first, second third, fourth, fifth, sixth, seventh, and eighth gate output signal lines GO1, GO2, GO3, GO4, GO5, GO6, GO7, and GO8 may transmit the first gate signal to the first demultiplexer circuit DMC1. Accordingly, the first demultiplexer transistor included in the first demultiplexer circuit DMC1 may be turned on.

In one or more embodiments, each of the first, second third, fourth, fifth, sixth, seventh, and eighth gate output signal lines GO1, GO2, GO3, GO4, GO5, GO6, GO7, and GO8 may be spaced (e.g., spaced apart) from each other in a plan view. In one or more embodiments, the plurality of third demultiplexer connecting lines DCL3 may be arranged in an order of the first gate output signal line GO1, the second gate output signal line GO2, the third gate output signal line GO3, the fourth gate output signal line GO4, the fifth gate output signal line GO5, the sixth gate output signal line GO6, the seventh gate output signal line GO7, and the eighth gate output signal line GO8 along the second direction DR2 at a constant interval from each other.

In one or more embodiments, the first, second third, fourth, fifth, sixth, seventh, and eighth gate output signal lines GO1, GO2, GO3, GO4, GO5, GO6, GO7, and GO8 may extend in a direction opposite to the first direction DR1 from the electrostatic discharge circuit ESC.

In one or more embodiments, lengths of at least two or more data output signal lines from among the first, second third, fourth, fifth, sixth, seventh, and eighth gate output signal lines GO1, GO2, GO3, GO4, GO5, GO6, GO7, and GO8 in the first direction DR1 may be different from each other. In one or more other embodiments, a length of each of the first, second third, fourth, fifth, sixth, seventh, and eighth gate output signal lines GO1, GO2, GO3, GO4, GO5, GO6, GO7, and GO8 in the first direction DR1 may be substantially the same. However, a length relationship of each of the signal lines included in the third demultiplexer connecting lines DCL3 according to one or more embodiments of the present disclosure in the first direction DR1 or the second direction DR2 may not be necessarily limited this.

The plurality of fourth demultiplexer connecting lines DCL4 may include a ninth gate output signal line GO9, a tenth gate output signal line GO10, an eleventh gate output signal line GO11, a twelfth gate output signal line GO12, a thirteenth gate output signal line GO13, a fourteenth gate output signal line GO14, a fifteenth gate output signal line GO15, a sixteenth gate output signal line GO16, a seventeenth gate output signal line GO17, an eighteenth gate output signal line GO18, and a nineteenth gate output signal line GO19. However, a number of signal lines included in the fourth demultiplexer connecting lines DCL4 according to one or more embodiments of the present disclosure may not be necessarily limited this.

The plurality of fourth demultiplexer connecting lines DCL4 may transmit the second gate signal received from the fourth pad connecting lines PCL4 to the second demultiplexer circuit DMC2. For example, each of the ninth, tenth, eleventh, twelfth, thirteenth, fourteenth, fifteenth, sixteenth, seventeenth, eighteenth, and nineteenth gate output signal lines GO9, GO10, GO11, GO12, GO13, GO14, GO15, GO16, GO17, GO18, and GO19 may transmit the second gate signal to the second demultiplexer circuit DMC2. Accordingly, the second demultiplexer transistor included in the second demultiplexer circuit DMC2 may be turned on.

In one or more embodiments, each of the ninth, tenth, eleventh, twelfth, thirteenth, fourteenth, fifteenth, sixteenth, seventeenth, eighteenth, and nineteenth gate output signal lines GO9, GO10, GO11, GO12, GO13, GO14, GO15, GO16, GO17, GO18, and GO19 may be spaced (e.g., spaced apart) from each other in a plan view. In one or more embodiments, the plurality of fourth demultiplexer connecting lines DCL4 may be arranged in an order of the ninth gate output signal line GO9, the tenth gate output signal line GO10, the eleventh gate output signal line GO11, the twelfth gate output signal line GO12, the thirteenth gate output signal line GO13, the fourteenth gate output signal line GO14, the fifteenth gate output signal line GO15, the sixteenth gate output signal line GO16, the seventeenth gate output signal line GO17, the eighteenth gate output signal line GO18, and the nineteenth gate output signal line GO19 along the second direction DR2 at a constant interval from each other.

In one or more embodiments, the ninth, tenth, eleventh, twelfth, thirteenth, fourteenth, fifteenth, sixteenth, seventeenth, eighteenth, and nineteenth gate output signal lines GO9, GO10, GO11, GO12, GO13, GO14, GO15, GO16, GO17, GO18, and GO19 may extend in a direction opposite to the first direction DR1 from the electrostatic discharge circuit ESC.

In one or more embodiments, lengths of at least two data output signal lines from among ninth, tenth, eleventh, twelfth, thirteenth, fourteenth, fifteenth, sixteenth, seventeenth, eighteenth, and nineteenth gate output signal lines GO9, GO10, GO11, GO12, GO13, GO14, GO15, GO16, GO17, GO18, and GO19 in the first direction DR1 may be different from each other. In one or more other embodiments, a length of each of the ninth, tenth, eleventh, twelfth, thirteenth, fourteenth, fifteenth, sixteenth, seventeenth, eighteenth, and nineteenth gate output signal lines GO9, GO10, GO11, GO12, GO13, GO14, GO15, GO16, GO17, GO18, and GO19 in the first direction DR1 may be substantially the same. However, a length relationship of each of the signal lines included in the fourth demultiplexer connecting lines DCL4 according to one or more embodiments of the present disclosure in the first direction DR1 or the second direction DR2 may not be necessarily limited this.

The plurality of fifth demultiplexer connecting lines DCL5 may include a twenty-third data output signal line DO23, a twenty-fourth data output signal line DO24, and a twenty-fifth data output signal line DO25. However, a number of signal lines included in the fifth demultiplexer connecting lines DCL5 according to one or more embodiments of the present disclosure may not be necessarily limited this. In one or more embodiments, each of the twenty-third data output signal line DO23, the twenty-fourth data output signal line DO24, and the twenty-fifth data output signal line DO25 may be spaced (e.g., spaced apart) from each other in a plan view.

The plurality of fifth demultiplexer connecting lines DCL5 may transmit the third touch signal received from the fifth pad connecting lines PCL5 to the touch panel TP. For example, each of the twenty-third data output signal line DO23, the twenty-fourth data output signal line DO24, and the twenty-fifth data output signal line DO25 may transmit the third touch signal to the touch panel TP.

In one or more embodiments, the electrostatic discharge circuit ESC may be disposed between the demultiplexer circuit DMC and the plurality of pad connecting lines PCL in a plan view. For example, the electrostatic discharge circuit ESC may be disposed in the first direction DR1 from the first demultiplexer circuit DMC1 in a plan view, and may be disposed in the opposite direction of the first direction DR1 from each of the plurality of pad connecting lines PCL.

In one or more embodiments, the electrostatic discharge circuit ESC may be spaced (e.g., spaced apart) from the demultiplexer circuit DMC in a plan view. Specifically, an end of the electrostatic discharge circuit ESC facing the opposite direction of the first direction DR1 may be spaced (e.g., spaced apart) from an end of the demultiplexer circuit DMC facing the first direction DR1 in a plan view.

In one or more embodiments, the electrostatic discharge circuit ESC may overlap each of the plurality of pad connecting lines PCL in a plan view. Specifically, the end portion facing the first direction DR1 of the electrostatic discharge circuit ESC may overlap in a plan view a portion facing in an opposite direction to the first direction DR1 of each of the plurality of pad connecting lines PCL (e.g., PCL1 to PCL5).

The electrostatic discharge circuit ESC may be disposed between the plurality of pad connecting lines PCL and the plurality of demultiplexer connecting lines DCL (e.g., DCL1 to DCL5). In one or more embodiments, the electrostatic discharge circuit ESC may overlap in a plan view a portion of each of the plurality of demultiplexer connecting lines DCL. Specifically, the end portion facing in an opposite direction to the first direction DR1 of the electrostatic discharge circuit ESC may overlap in a plan view a portion of each of the plurality of demultiplexer connecting lines DCL.

The electrostatic discharge circuit ESC may be electrically connected to each of the plurality of pad connecting lines PCL and the plurality of demultiplexer connecting lines DCL. Specifically, the electrostatic discharge circuit ESC may connect each of a plurality of pad connecting lines PCL to each of a plurality of demultiplexer connecting lines DCL corresponding to each of the plurality of pad connecting lines PCL.

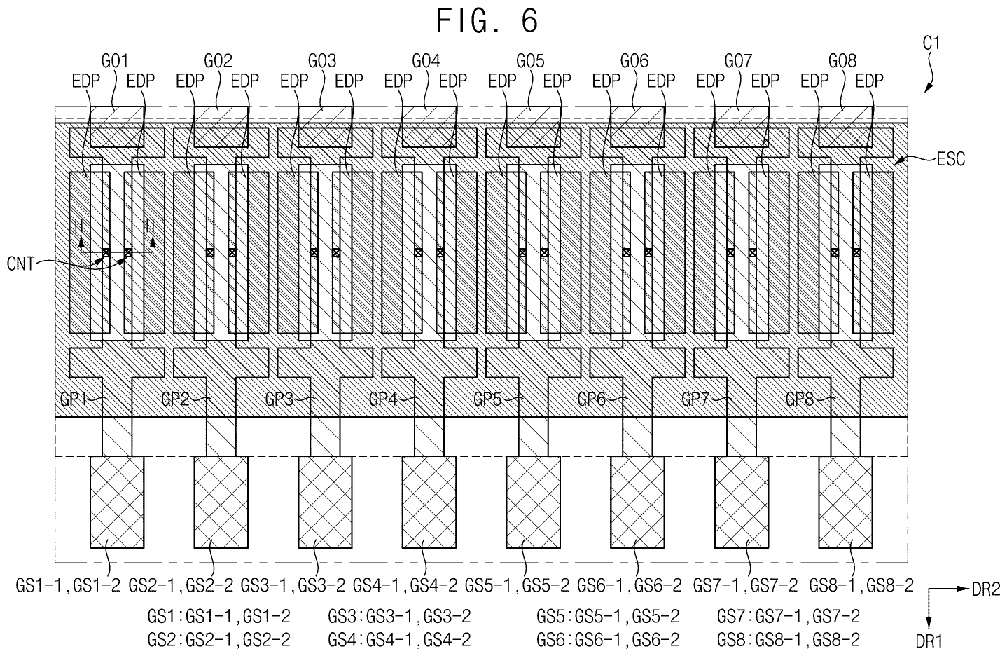

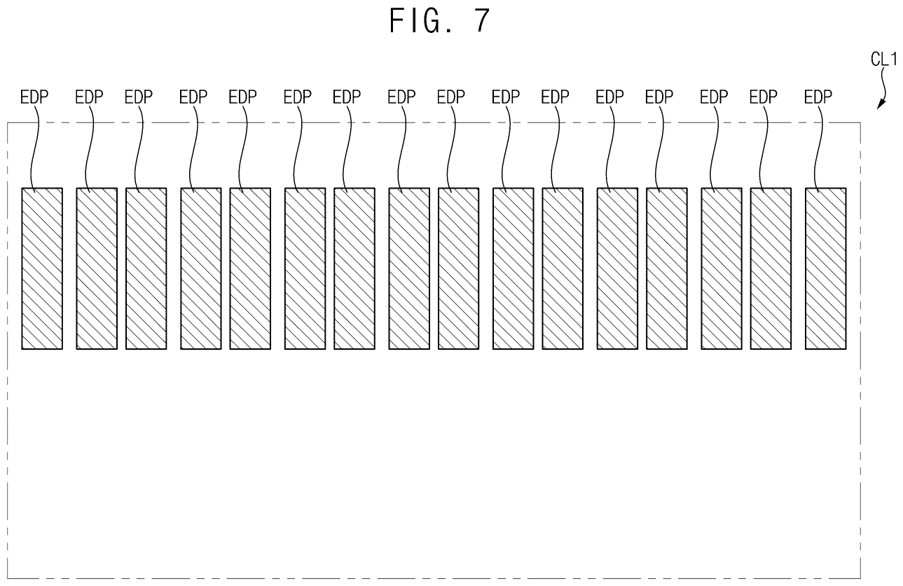

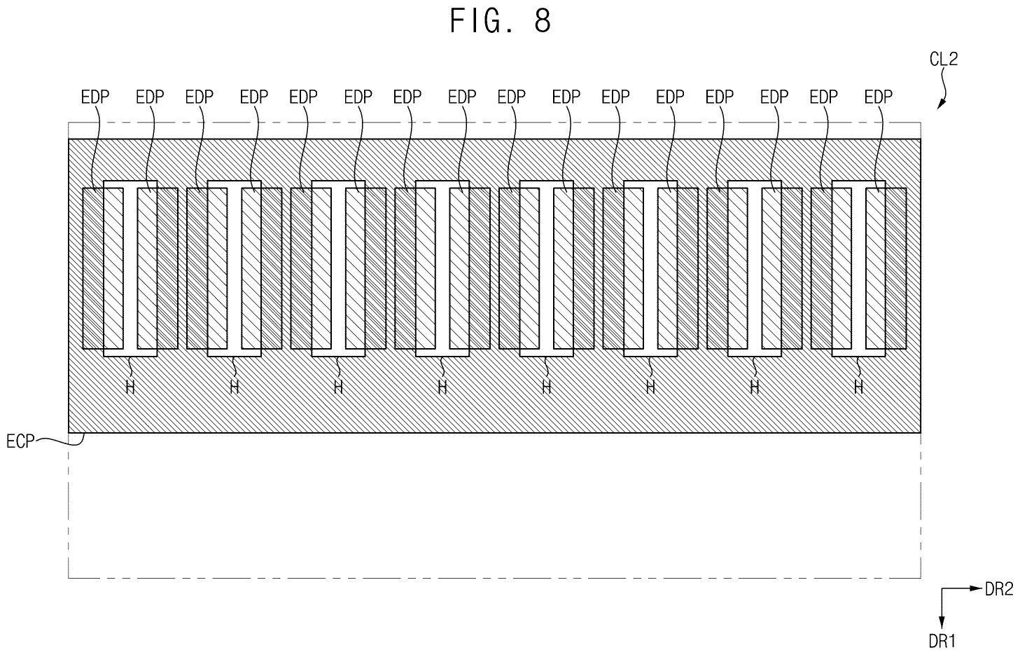

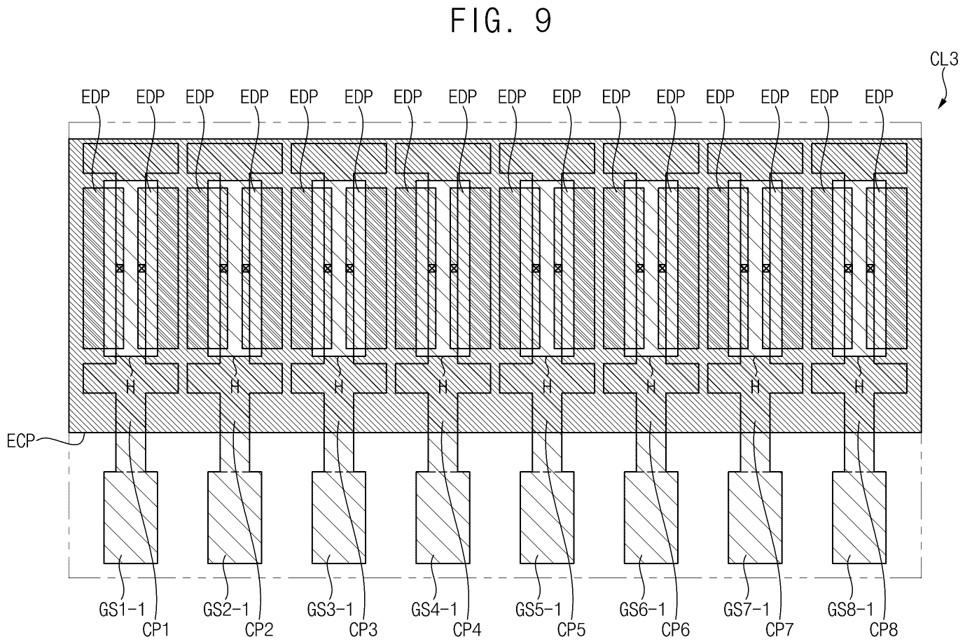

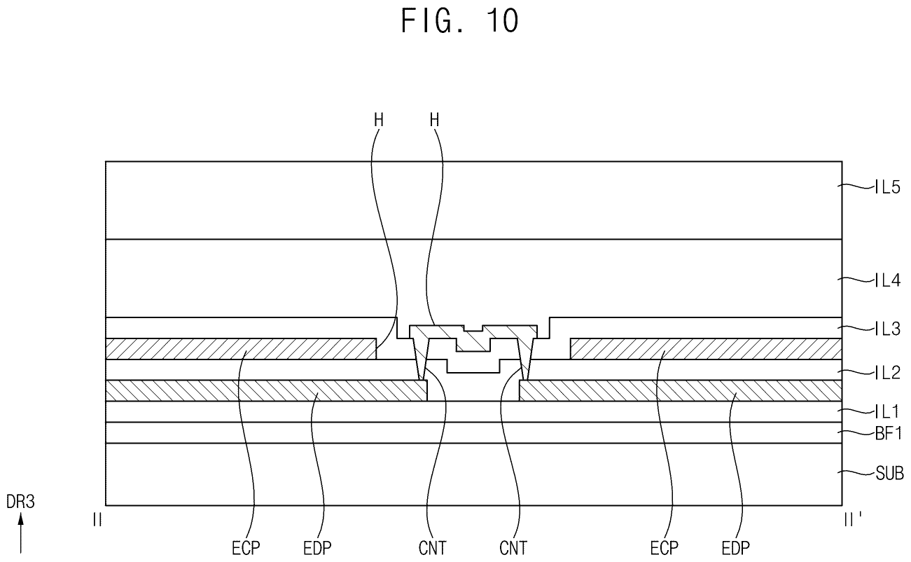

FIG. 6 is an enlarged plan view illustrating an area C1 of FIG. 5. FIGS. 7, 8, and 9 are layout diagrams for explaining an arrangement of components included in an electrostatic discharge circuit of FIG. 6. FIG. 10 is a cross-sectional view illustrating a cross-section taken along the line II-II′ of FIG. 6.

An arrangement of the layered structure or insulating layers (e.g., an arrangement of the first, second, third, fourth, and fifth insulating layers IL1, IL2, IL3, IL4, and IL5 stacked along the third direction DR3 of a cross-section of the electrostatic discharge circuit ESC described with reference to FIG. 10 may be substantially a same as or similar to an arrangement of the layered structure or insulating layers stacked along the third direction DR3 of a cross-section of the display device DD described with reference to FIG. 3. Hereinafter, any content overlapping with the content described with reference to FIG. 3 may be omitted or briefly described.

Referring to FIGS. 6, 7, 8, 9, and 10, the electrostatic discharge circuit ESC may include a first conductive layer CL1, a second conductive layer CL2, and a third conductive layer CL3. For example, the first conductive layer CL1, the second conductive layer CL2, and the third conductive layer CL3 may be sequentially staked on a substrate (e.g., the substrate SUB of FIG. 3) along the third direction DR3.

The first conductive layer CL1 may include a plurality of electrostatic dissipation patterns EDP. The second conductive layer CL2 may include an electrostatic capacitor electrode ECP. The third conductive layer CL3 may include a first connecting pattern CP1, a second connecting pattern CP2, a third connecting pattern CP3, a fourth connecting pattern CP4, a fifth connecting pattern CP5, a sixth connecting pattern CP6, a seventh connecting pattern CP7, and an eighth connecting pattern CP8.

In this specification, the first connecting pattern CP1, the second connecting pattern CP2, the third connecting pattern CP3, the fourth connecting pattern CP4, the fifth connecting pattern CP5, the sixth connecting pattern CP6, the seventh connecting pattern CP7, and the eighth connecting pattern CP8 may be referred to as a plurality of connecting patterns.

Referring further to FIGS. 3, 7, and 10, the plurality of electrostatic dissipation patterns EDP may be disposed on the first insulating layer IL1. In one or more embodiments, the plurality of electrostatic dissipation patterns EDP and the first gate electrode GE1 may be disposed in a same layer. For example, the plurality of electrostatic dissipation patterns EDP and the first gate electrode GE1 may include a same material. For example, the plurality of electrostatic dissipation patterns EDP and the first gate electrode GE1 may be formed through a same process.

In one or more embodiments, each of the plurality of electrostatic dissipation patterns EDP may be spaced (e.g., spaced apart) from each other in a plan view. For example, each of the plurality of electrostatic dissipation patterns EDP may be spaced (e.g., spaced apart) from each other in a plan view and arranged along a second direction DR2.

The electrostatic capacitor electrode ECP may be disposed on the second insulating layer IL2. In one or more embodiments, the electrostatic capacitor electrode ECP and the second gate electrode GE2 may be disposed on (e.g., in) a same layer. For example, the electrostatic capacitor electrode ECP and the second gate electrode GE2 may include a same material. For example, the electrostatic capacitor electrode ECP and the second gate electrode GE2 may be formed through a same process.

However, an arrangement of the plurality of electrostatic dissipation patterns EDP and the electrostatic capacitor electrode ECP according to one or more embodiments of the present disclosure may not be necessarily limited this. For example, the plurality of electrostatic dissipation patterns EDP may be disposed on the electrostatic capacitor electrode ECP. Specifically, the plurality of electrostatic dissipation patterns EDP and the second gate electrode GE2 may be disposed in a same layer, and the electrostatic capacitor electrode ECP and the first gate electrode GE1 may be disposed in a same layer.

In one or more embodiments, the electrostatic capacitor electrode ECP may overlap the plurality of electrostatic dissipation patterns EDP in a plan view. In one or more embodiments, the electrostatic capacitor electrode ECP may extend along the second direction DR2. For example, the electrostatic capacitor electrode ECP may extend along the second direction DR2 and overlap each of the plurality of electrostatic dissipation patterns EDP in a plan view. In one or more embodiments, a length of the electrostatic capacitor electrode ECP in the first direction DR1 may be smaller than a length of the electrostatic capacitor electrode ECP in the second direction DR2 in a plan view.

In one or more embodiments, a length of a portion of the electrostatic capacitor electrode ECP that overlaps with one electrostatic dissipation pattern EDP from among the plurality of the electrostatic dissipation patterns EDP in the first direction DR1 may be greater than a length of a portion of the electrostatic capacitor electrode ECP that overlaps with one electrostatic dissipation pattern EDP from among the plurality of the electrostatic dissipation patterns EDP in the second direction DR2, in a plan view.

For example, the length of a portion of the electrostatic capacitor electrode ECP that overlaps with the one electrostatic dissipation pattern EDP in the first direction DR1 may be about 100 μm to about 300 μm. Preferably, the length of a portion of the electrostatic capacitor electrode ECP that overlaps with the one electrostatic dissipation pattern EDP in the first direction DR1 may be about 150 μm to about 200 μm. More preferably, the length of a portion of the electrostatic capacitor electrode ECP that overlaps with the one electrostatic dissipation pattern EDP in the first direction DR1 may be about 175 μm.

For example, the length of a portion of the electrostatic capacitor electrode ECP that overlaps with the one electrostatic dissipation pattern EDP in the second direction DR2 may be about 10 μm to about 30 μm. Preferably, the length of a portion of the electrostatic capacitor electrode ECP that overlaps with the one electrostatic dissipation pattern EDP in the second direction DR2 may be about 15 μm to about 20 μm. More preferably, the length of a portion of the electrostatic capacitor electrode ECP that overlaps with the one electrostatic dissipation pattern EDP in the second direction DR2 may be about 18 μm.

In one or more embodiments, the electrostatic capacitor electrode ECP may be defined with at least one hole H exposing an upper surface of the plurality of electrostatic dissipation patterns EDP. For example, the plurality of holes exposing the upper surface of each of the plurality of electrostatic dissipation patterns EDP may be arranged along the second direction DR2.

The first connecting pattern CP1, the second connecting pattern CP2, the third connecting pattern CP3, the fourth connecting pattern CP4, the fifth connecting pattern CP5, the sixth connecting pattern CP6, the seventh connecting pattern CP7, and the eighth connecting pattern CP8 may be disposed on the third insulating layer IL3. In one or more embodiments, the first connecting pattern CP1, the second connecting pattern CP2, the third connecting pattern CP3, the fourth connecting pattern CP4, the fifth connecting pattern CP5, the sixth connecting pattern CP6, the seventh connecting pattern CP7, the eighth connecting pattern CP8, the source electrode SE and the drain electrode DE may be disposed in a same layer.

For example, the first connecting pattern CP1, the second connecting pattern CP2, the third connecting pattern CP3, the fourth connecting pattern CP4, the fifth connecting pattern CP5, the sixth connecting pattern CP6, the seventh connecting pattern CP7, the eighth connecting pattern CP8, the source electrode SE and the drain electrode DE may include a same material. For example, the first connecting pattern CP1, the second connecting pattern CP2, the third connecting pattern CP3, the fourth connecting pattern CP4, the fifth connecting pattern CP5, the sixth connecting pattern CP6, the seventh connecting pattern CP7, the eighth connecting pattern CP8, the source electrode SE and the drain electrode DE may be formed through a same process.

The first connecting pattern CP1 may electrically connect the first gate signal line GS1 and the first gate output signal line GO1 to each other. In one or more embodiments, the first gate output signal line GO1 and the contact electrode CTE may be disposed in a same layer. For example, an end of the first connecting pattern CP1 facing in the opposite direction to the first direction DR1 may contact the first gate output signal line GO1 through a contact hole penetrating the fourth insulating layer IL4 in the thickness direction (e.g., the third direction DR3).

In one or more embodiments, the first gate signal line GS1 may include a first portion GS1-1 which is disposed in a same layer as the source electrode SE and the drain electrode DE and a second portion GS1-2 disposed in a same layer as the contact electrode CTE. The first portion GS1-1 of the first gate signal line GS1 and the second portion GS1-2 of the first gate signal line GS1 may be electrically connected. In one or more embodiments, the first portion GS1-1 of the first gate signal line GS1 and the first connecting pattern CP1 may be formed integrally.

In one or more embodiments, the first connecting pattern CP1 may extend along the first direction DR1. In one or more embodiments, the first connecting pattern CP1 may overlap a plurality of electrostatic dissipation patterns EDP in a plan view. For example, the first connecting pattern CP1 may overlap two electrostatic dissipation patterns EDP adjacent to the first connecting pattern CP1 from among the plurality of electrostatic dissipation patterns EDP in a plan view.

In one or more embodiments, a contact hole CNT penetrating the second insulating layer IL2 and the third insulating layer IL3 in a thickness direction (e.g., the third direction DR3) may be defined. The first connecting pattern CP1 may contact two electrostatic dissipation patterns EDP through the contact hole. The second connecting pattern CP2 may electrically connect the second gate signal line GS2 and the second gate output signal line GO2 to each other. In one or more embodiments, the second gate output signal line GO2 may be disposed in a same layer as the contact electrode CTE. For example, an end of the second connecting pattern CP2 facing in the opposite direction to the first direction DR1 may contact the second gate output signal line GO2 through a contact hole penetrating the fourth insulating layer IL4 in the thickness direction (e.g., the third direction DR3).

In one or more embodiments, the second gate signal line GS2 may include a first portion GS2-1 which is disposed in a same layer as the source electrode SE and the drain electrode DE, and a second portion GS2-2 which is disposed in a same layer as the contact electrode CTE. The first portion GS2-1 of the second gate signal line GS2 and the second portion GS2-2 of the second gate signal line GS2 may be electrically connected. In one or more embodiments, the first portion GS2-1 of the second gate signal line GS2 and the second connecting pattern CP2 may be formed integrally.

In one or more embodiments, the second connecting pattern CP2 may extend along the first direction DR1. In one or more embodiments, the second connecting pattern CP2 may overlap a plurality of electrostatic dissipation patterns EDP in a plan view. For example, the second connecting pattern CP2 may overlap two electrostatic dissipation patterns EDP adjacent to the second connecting pattern CP2 from among the plurality of electrostatic dissipation patterns EDP in a plan view.

In one or more embodiments, the second connecting pattern CP2 may contact two electrostatic dissipation patterns EDP. For example, the second connecting pattern CP2 may contact two electrostatic dissipation patterns EDP adjacent to the second connecting pattern CP2 through a contact hole CNT penetrating the second insulating layer IL2 and the third insulating layer IL3 in the thickness direction (e.g., the third direction DR3).

The third connecting pattern CP3 may electrically connect the third gate signal line GS3 and the third gate output signal line GO3 to each other. In one or more embodiments, the third gate output signal line GO3 may be disposed in a same layer as the contact electrode CTE. For example, an end of the third connecting pattern CP3 facing in the opposite direction to the first direction DR1 may contact the third gate output signal line GO3 through a contact hole penetrating the fourth insulating layer IL4 in the thickness direction (e.g., the third direction DR3).

In one or more embodiments, the third gate signal line GS3 may include a first portion GS3-1 which disposed in a same layer as the source electrode SE and the drain electrode DE and a second portion GS3-2 which disposed in a same layer as the contact electrode CTE. The first portion GS3-1 of the third gate signal line GS3 and the second portion GS3-2 of the third gate signal line GS3 may be electrically connected. In one or more embodiments, the first portion GS3-1 of the third gate signal line GS3 and the third connecting pattern CP3 may be formed integrally.

In one or more embodiments, the third connecting pattern CP3 may extend along the first direction DR1. In one or more embodiments, the third connecting pattern CP3 may overlap a plurality of electrostatic dissipation patterns EDP in a plan view. For example, the third connecting pattern CP3 may overlap two electrostatic dissipation patterns adjacent to the third connecting pattern CP3 from among a plurality of electrostatic dissipation patterns EDP in a plan view. In one or more embodiments, the third connecting pattern CP3 may contact two electrostatic dissipation patterns. For example, the third connecting pattern CP3 may contact two electrostatic dissipation patterns adjacent to the third connecting pattern CP3 through a contact hole CNT penetrating the second insulating layer IL2 and the third insulating layer IL3 in the thickness direction (e.g., the third direction DR3).

The fourth connecting pattern CP4 may electrically connect the fourth gate signal line GS4 and the fourth gate output signal line GO4 to each other. In one or more embodiments, the fourth gate output signal line GO4 may be disposed in a same layer as the contact electrode CTE. For example, an end of the fourth connecting pattern CP4 facing in the opposite direction to the first direction DR1 may contact the fourth gate output signal line GO4 through a contact hole penetrating the fourth insulating layer IL4 in the thickness direction (e.g., the third direction DR3).

In one or more embodiments, the fourth gate signal line GS4 may include a first portion GS4-1 which is disposed in a same layer as the source electrode SE and the drain electrode DE, and a second portion GS4-2 which is disposed in a same layer as the contact electrode CTE. The first portion GS4-1 of the fourth gate signal line GS4 and the second portion GS4-2 of the fourth gate signal line GS4 may be electrically connected. In one or more embodiments, the first portion GS4-1 of the fourth gate signal line GS4 and the fourth connecting pattern CP4 may be formed integrally.

In one or more embodiments, the fourth connecting pattern CP4 may extend along the first direction DR1. In one or more embodiments, the fourth connecting pattern CP4 may overlap a plurality of electrostatic dissipation patterns EDP in a plan view. For example, the fourth connecting pattern CP4 may overlap two electrostatic dissipation patterns adjacent to the fourth connecting pattern CP4 from among the plurality of electrostatic dissipation patterns EDP in a plan view.

In one or more embodiments, the fourth connecting pattern CP4 may contact two electrostatic dissipation patterns EDP. For example, the fourth connecting pattern CP4 may contact two electrostatic dissipation patterns EDP adjacent to the fourth connecting pattern CP4 through a contact hole CNT penetrating the second insulating layer IL2 and the third insulating layer IL3 in the thickness direction (e.g., the third direction DR3).

The fifth connecting pattern CP5 may electrically connect the fifth gate signal line GS5 and the fifth gate output signal line GO5 to each other. In one or more embodiments, the fifth gate output signal line GO5 and the contact electrode CTE may be disposed in a same layer. For example, an end of the fifth connecting pattern CP5 facing in the opposite direction to the first direction DR1 may contact the fifth gate output signal line GO5 through a contact hole penetrating the fourth insulating layer IL4 in the thickness direction (e.g., the third direction DR3).

In one or more embodiments, the fifth gate signal line GS5 may include a first portion GS5-1 disposed in a same layer as the source electrode SE and the drain electrode DE and a second portion GS5-2 disposed in a same layer as the contact electrode CTE. The first portion GS5-1 of the fifth gate signal line GS5 and the second portion GS5-2 of the fifth gate signal line GS5 may be electrically connected. In one or more embodiments, the first portion GS5-1 of the fifth gate signal line GS5 and the fifth connecting pattern CP5 may be formed integrally.

In one or more embodiment, the fifth connecting pattern CP5 may extend along the first direction DR1. In one or more embodiments, the fifth connecting pattern CP5 may overlap a plurality of electrostatic dissipation patterns EDP in a plan view. For example, the fifth connecting pattern CP5 may overlap two electrostatic dissipation patterns adjacent to the fifth connecting pattern CP5 from among a plurality of electrostatic dissipation patterns EDP in a plan view.

In one or more embodiments, the fifth connecting pattern CP5 may contact two electrostatic dissipation patterns. For example, the fifth connecting pattern CP5 may contact two electrostatic dissipation patterns adjacent to the fifth connecting pattern CP5 through a contact hole CNT penetrating the second insulating layer IL2 and the third insulating layer IL3 in the thickness direction (e.g., the third direction DR3).

The sixth connecting pattern CP6 may electrically connect the sixth gate signal line GS6 and the sixth gate output signal line GO6 to each other. In one or more embodiments, the sixth gate output signal line GO6 and the contact electrode CTE may be disposed in a same layer. For example, an end portion facing in the opposite direction of the first direction DR1 of the sixth connecting pattern CP6 may contact the sixth gate output signal line GO6 through a contact hole penetrating the fourth insulating layer IL4 in the thickness direction (e.g., the third direction DR3).

In one or more embodiments, the sixth gate signal line GS6 may include a first portion GS6-1 disposed in a same layer as the source electrode SE and the drain electrode DE and a second portion GS6-2 disposed in a same layer as the contact electrode CTE. The first portion GS6-1 of the sixth gate signal line GS6 and the second portion GS6-2 of the sixth gate signal line GS6 may be electrically connected. In one or more embodiments, the first portion GS6-1 of the sixth gate signal line GS6 and the sixth connecting pattern CP6 may be formed integrally.

In one or more embodiments, the sixth connecting pattern CP6 may extend along the first direction DR1. In one or more embodiments, the sixth connecting pattern CP6 may overlap with a plurality of electrostatic dissipation patterns EDP in a plan view. For example, the sixth connecting pattern CP6 may overlap with two electrostatic dissipation patterns adjacent to the sixth connecting pattern CP6 from among the plurality of electrostatic dissipation patterns EDP.

In one or more embodiments, the sixth connecting pattern CP6 may contact two electrostatic dissipation patterns. For example, the sixth connecting pattern CP6 may contact two electrostatic dissipation patterns adjacent to the sixth connecting pattern CP6 through a contact hole CNT penetrating the second insulating layer IL2 and the third insulating layer IL3 in the thickness direction (e.g., the third direction DR3).

The seventh connecting pattern CP7 may electrically connect the seventh gate signal line GS7 and the seventh gate output signal line GO7 to each other. In one or more embodiments, the seventh gate signal line GS7 and the seventh gate output signal line GO7 may be disposed in a same layer as the contact electrode CTE. Specifically, an end of the seventh connecting pattern CP7 facing the first direction DR1 may contact the seventh gate signal line GS7 through a contact hole penetrating the fourth insulating layer IL4 in the thickness direction (e.g., the third direction DR3).

In one or more embodiments, the seventh gate signal line GS7 may include a first portion GS7-1 disposed in a same layer as the source electrode SE and the drain electrode DE, and a second portion GS7-2 disposed in a same layer as the contact electrode CTE. The first portion GS7-1 of the seventh gate signal line GS7 and the second portion GS7-2 of the seventh gate signal line GS7 may be electrically connected. In one or more embodiments, the first portion GS7-1 of the seventh gate signal line GS7 and the seventh connecting pattern CP7 may be formed integrally.

In one or more embodiments, the seventh connecting pattern CP7 may extend along the first direction DR1. In one or more embodiments, the seventh connecting pattern CP7 may overlap a plurality of electrostatic dissipation patterns EDP in a plan view. For example, the seventh connecting pattern CP7 may overlap two electrostatic dissipation patterns adjacent to the seventh connecting pattern CP7 from among the plurality of electrostatic dissipation patterns EDP in a plan view.

In one or more embodiments, the seventh connecting pattern CP7 may contact two electrostatic dissipation patterns. For example, the seventh connecting pattern CP7 may contact two electrostatic dissipation patterns adjacent to the seventh connecting pattern CP7 through a contact hole CNT penetrating the second insulating layer IL2 and the third insulating layer IL3 in the thickness direction (e.g., the third direction DR3).

The eighth connecting pattern CP8 may electrically connect the eighth gate signal line GS8 and the eighth gate output signal line GO8 to each other. In one or more embodiments, the eighth gate signal line GS8 and the eighth gate output signal line GO8 may be disposed in a same layer as the contact electrode CTE. Specifically, an end of the eighth connecting pattern CP8 facing the first direction DR1 may contact the eighth gate signal line GS8 through a contact hole penetrating the fourth insulating layer IL4 in the thickness direction (e.g., the third direction DR3).

In one or more embodiments, the eighth gate signal line GS8 may include a first portion GS8-1 disposed in a same layer as the source electrode SE and the drain electrode DE and a second portion GS8-2 disposed in a same layer as the contact electrode CTE. The first portion GS8-1 of the eighth gate signal line GS8 and the second portion GS8-2 of the eighth gate signal line GS8 may be electrically connected. In one or more embodiments, the first portion GS8-1 of the eighth gate signal line GS8 and the eighth connecting pattern CP8 may be formed integrally.

In one or more embodiments, the eighth connecting pattern CP8 may extend along the first direction DR1. In one or more embodiments, the eighth connecting pattern CP8 may overlap a plurality of electrostatic dissipation patterns EDP in a plan view. For example, the eighth connecting pattern CP8 may overlap two electrostatic dissipation patterns adjacent to the eighth connecting pattern CP8 from among the plurality of electrostatic dissipation patterns EDP in a plan view.

In one or more embodiments, the eighth connecting pattern CP8 may contact two electrostatic dissipation patterns. For example, the eighth connecting pattern CP8 may contact two electrostatic dissipation patterns adjacent to the eighth connecting pattern CP8 through a contact hole CNT penetrating the second insulating layer IL2 and the third insulating layer IL3 in the thickness direction (e.g., the third direction DR3).

In this specification, the first buffer layer BF1 and the first insulating layer IL1 may be referred to as a first insulating structure, and the second insulating layer IL2 and the third insulating layer IL3 may be referred to as a second insulating structure.

FIG. 11 is a plan view illustrating an enlarged example of an area D1 of FIG. 5. FIG. 12 is a plan view illustrating an enlarged example of an area D2 of FIG. 5. FIG. 13 is a plan view illustrating an enlarged example of an area D3 of FIG. 5.

Referring to FIGS. 4, 5, 11, 12, and 13, a first demultiplexer transistor DMT1 may include a first demultiplexer active layer DACT1, a first vertical gate pattern VGP1, a second vertical gate pattern VGP2, a first upper connecting pattern TCP1, a second upper connecting pattern TCP2, and a third upper connecting pattern TCP3. In addition, a plurality of lines may be disposed between the first demultiplexer circuit DMC1 and the second demultiplexer circuit DMC2 in a plan view, extending along a first direction DR1 or a second direction DR2, and included in a display panel DP. The plurality of lines may include a first lower vertical pattern LVP1, a second lower vertical pattern LVP2, a first upper horizontal pattern THP1, and a second upper horizontal pattern THP2.

The second demultiplexer transistor DMT2 may include a second demultiplexer active layer DACT2, a third vertical gate pattern VGP3, a fourth upper connecting pattern TCP4, and a fifth upper connecting pattern TCP5. In addition, a plurality of lines may be disposed between the second demultiplexer circuit DMC2 and the third demultiplexer circuit DMC3 in a plan view, extending along the first direction DR1 or the second direction DR2, and included in the display panel DP. The plurality of lines may include a third lower vertical pattern LVP3, a third upper horizontal pattern THP3, and a fourth upper horizontal pattern THP4.

The third demultiplexer transistor DMT3 may include a third demultiplexer active layer DACT3, a fifth vertical gate pattern VGP5, a sixth upper connecting pattern TCP6, and a seventh upper connecting pattern TCP7. In addition, a fourth vertical gate pattern VGP4 extending along the first direction DR1 may be disposed between the second demultiplexer circuit DMC2 and the third demultiplexer circuit DMC3 in a plan view. In addition, a plurality of lines extending along the first direction DR1 or the second direction DR2 and included in the display panel DP may be disposed in a direction opposite to the first direction DR1 of the third demultiplexer circuit DMC3 in a plan view. The plurality of lines may include a fourth lower vertical pattern LVP4, a fifth upper horizontal pattern THP5, and a sixth upper horizontal pattern THP6.

Referring further to FIG. 3, in one or more embodiments, the first demultiplexer active layer DACT1 and as the active layer ACT may be disposed in a same layer. The first vertical gate pattern VGP1 may extend in the first direction DR1. In one or more embodiments, the first vertical gate pattern VGP1 and the first gate electrode GE1 may be disposed in a same layer.

In one or more embodiments, the first vertical gate pattern VGP1 may overlap the first demultiplexer active layer DACT1 in a plan view. The first vertical gate pattern VGP1 may be a gate electrode of the first demultiplexer transistor DMT1. In one or more embodiments, the first vertical gate pattern VGP1 may be electrically connected to one pad connecting line of the third pad connecting lines PCL3. For example, the first vertical gate pattern VGP1 may receive the first gate signal from the third pad connecting lines PCL3.

The second vertical gate pattern VGP2 may extend in the first direction DR1. In one or more embodiments, the second vertical gate pattern VGP2 and the first gate electrode GE1 may be disposed in a same layer. In one or more embodiments, the second vertical gate pattern VGP2 may be spaced (e.g., spaced apart) from the first vertical gate pattern VGP1 in a plan view.

In one or more embodiments, the second vertical gate pattern VGP2 may overlap the second demultiplexer active layer DACT2 in a plan view. The second vertical gate pattern VGP2 may be a gate electrode of the first demultiplexer transistor DMT1. For example, the first demultiplexer transistor DMT1 may have a dual-transistor structure having two gate electrodes. In one or more embodiments, the second vertical gate pattern VGP2 may be electrically connected to one of the third pad connecting lines PCL3. For example, the second vertical gate pattern VGP2 may receive the first gate signal from the third pad connecting lines PCL3.

In one or more embodiments, each of the first upper connecting pattern TCP1, the second upper connecting pattern TCP2, and the third upper connecting pattern TCP3 may overlap the first demultiplexer active layer DACT1 in a plan view.

In one or more embodiments, the first upper connecting pattern TCP1, the second upper connecting pattern TCP2, and the third upper connecting pattern TCP3 may be spaced (e.g., spaced apart) from the first vertical gate pattern VGP1 and the second vertical gate pattern VGP2 in a plan view.

In one or more embodiments, the first upper connecting pattern TCP1, the second upper connecting pattern TCP2, and the third upper connecting pattern TCP3 may be disposed in a same layer as the source electrode SE and the drain electrode DE.

In one or more embodiments, the first lower vertical pattern LVP1 may overlap each of the third upper connecting pattern TCP3 and the first upper horizontal pattern THP1 in a plan view. In one or more embodiments, the second lower vertical pattern LVP2 may overlap each of the second upper connecting pattern TCP2, the first upper horizontal pattern THP1, and the second upper horizontal pattern THP2 in a plan view. \

In one or more embodiments, each of the first lower vertical pattern LVP1 and the second lower vertical pattern LVP2 may extend along the first direction DR1. In one or more embodiments, each of the first lower vertical pattern LVP1 and the second lower vertical pattern LVP2 may be spaced (e.g., spaced apart) from each other in a plan view. In one or more embodiments, the first lower vertical pattern LVP1 and the second lower vertical pattern LVP2 may be disposed in a same layer as the second gate electrode GE2.

In one or more embodiments, each of the first upper horizontal pattern THP1 and the second upper horizontal pattern THP2 may extend in the second direction DR2. In one or more embodiments, the first upper horizontal pattern THP1 and the second upper horizontal pattern THP2 may be disposed in a same layer as the source electrode SE and the drain electrode DE.

The second demultiplexer active layer DACT2 may be disposed in a same layer as the first demultiplexer active layer DACT1. The third vertical gate pattern VGP3 may extend in the first direction DR1. In one or more embodiments, the third vertical gate pattern VGP3 may be disposed in a same layer as the first vertical gate pattern VGP1.

In one or more embodiments, the third vertical gate pattern VGP3 may overlap the second demultiplexer active layer DACT2 in a plan view. The third vertical gate pattern VGP3 may be a gate electrode of the second demultiplexer transistor DMT2. In one or more embodiments, the third vertical gate pattern VGP3 may be electrically connected to one of the fourth pad connecting lines PCL4. For example, the third vertical gate pattern VGP3 may receive the second gate signal from the fourth pad connecting lines PCL4.

In one or more embodiments, each of the fourth upper connecting pattern TCP4 and the fifth upper connecting pattern TCP5 may overlap the second demultiplexer active layer DACT2 in a plan view. In one or more embodiments, each of the fourth upper connecting pattern TCP4 and the fifth upper connecting pattern TCP5 may be spaced (e.g., spaced apart) from the third vertical gate pattern VGP3 in a plan view. In one or more embodiments, the fourth upper connecting pattern TCP4 and the fifth upper connecting pattern TCP5 may be disposed in a same layer as the first upper connecting pattern TCP1, the second upper connecting pattern TCP2, and the third upper connecting pattern TCP3.

In one or more embodiments, the third lower vertical pattern LVP3 may extend along the first direction DR1. In one or more embodiments, the third lower vertical pattern LVP3 may overlap with each of the fifth upper connecting pattern TCP5, the third upper horizontal pattern THP3, and the fourth upper horizontal pattern THP4 in a plan view.

In one or more embodiments, each of the third upper horizontal pattern THP3 and the fourth upper horizontal pattern THP4 may extend along the second direction DR2. In one or more embodiments, each of the third upper horizontal pattern THP3 and the fourth upper horizontal pattern THP4 may be spaced (e.g., spaced apart) from each other in a plan view. In one or more embodiments, the third upper horizontal pattern THP3 and the fourth upper horizontal pattern THP4 may be disposed in a same layer as the first lower vertical pattern LVP1 and the second lower vertical pattern LVP2.

The third demultiplexer active layer DACT3 may be disposed in a same layer as the second demultiplexer active layer DACT2. In one or more embodiments, the fourth vertical gate pattern VGP4 and the fifth vertical gate pattern VGP5 may be disposed in a same layer as the third vertical gate pattern VGP3. In one or more embodiments, each of the fourth vertical gate pattern VGP4 and the fifth vertical gate pattern VGP5 may be spaced (e.g., spaced apart) from each other in the first direction DR1.

In one or more embodiments, the fourth vertical gate pattern VGP4 may overlap the sixth upper connecting pattern TCP6 in a plan view. In one or more embodiments, the fifth vertical gate pattern VGP5 may overlap the third demultiplexer active layer DACT3 in a plan view. The fifth vertical gate pattern VGP5 may be a gate electrode of the third demultiplexer transistor DMT3.

In one or more embodiments, each of the sixth upper connecting pattern TCP6 and the seventh upper connecting pattern TCP7 may overlap with the third demultiplexer active layer DACT3 in a plan view. In one or more embodiments, each of the sixth upper connecting pattern TCP6 and the seventh upper connecting pattern TCP7 may be spaced (e.g., spaced apart) from each other in a plan view. In one or more embodiments, the sixth upper connecting pattern TCP6 and the seventh upper connecting pattern TCP7 may be disposed in a same layer as the fourth upper connecting pattern TCP4 and the fifth upper connecting pattern TCP5.

In one or more embodiments, the fourth lower vertical pattern LVP4 may extend along the first direction DR1. In one or more embodiments, the fourth lower vertical pattern LVP4 may overlap with each of the seventh upper connecting pattern TCP7, the fifth upper horizontal pattern THP5, and the sixth upper horizontal pattern THP6 in a plan view.

In one or more embodiments, each of the fifth upper horizontal pattern THP5 and the sixth upper horizontal pattern THP6 may extend along the second direction DR2. In one or more embodiments, each of the fifth upper horizontal pattern THP5 and the sixth upper horizontal pattern THP6 may be spaced (e.g., spaced apart) from each other in a plan view. In one or more embodiments, the fifth upper horizontal pattern THP5 and the sixth upper horizontal pattern THP6 may be disposed in a same layer as the third upper horizontal pattern THP3 and the fourth upper horizontal pattern THP4.

In one or more embodiments, a number of first demultiplexer transistors DMT1 included in the first demultiplexer circuit DMC1 may be smaller than a number of second demultiplexer transistors DMT2 included in the second demultiplexer circuit DMC2. In one or more embodiments, the number of first demultiplexer transistors DMT1 included in the first demultiplexer circuit DMC1 may be smaller than a number of third demultiplexer transistors DMT3 included in the third demultiplexer circuit DMC3.

As described above, in the display device DD, the electrostatic discharge circuit ESC may include the plurality of electrostatic dissipation patterns EDP, the electrostatic discharge capacitor electrode ECP overlapping the plurality of electrostatic dissipation patterns EDP in a plan view, and connecting patterns (e.g., first, second, third, fourth, fifth, sixth, seventh, eighth, ninth and tenth connecting patterns CP1, CP2, CP3, CP4, CP5, CP6, CP7, CP8, CP9, and CP10) electrically connected to the plurality of electrostatic dissipation patterns EDP through contact holes. Accordingly, when the touch panel TP is driven, charges may be induced through the plurality of electrostatic dissipation patterns EDP, the electrostatic discharge capacitor electrode ECP, and the connecting patterns to control static electricity, so that the electrostatic discharge (ESD) phenomenon generated in the demultiplexer circuit DMC and a peripheral area of the demultiplexer circuit DMC may be prevented. Accordingly, without affecting a sensitivity of touch signals transmitted to the touch panel TP, a degradation generated in transistors (e.g., first, second, and third demultiplexer transistors DMT1, DMT2, and DMT3) included in the demultiplexer circuit DMC may be prevented. Accordingly, a touch function of the display device 1 may be improved.

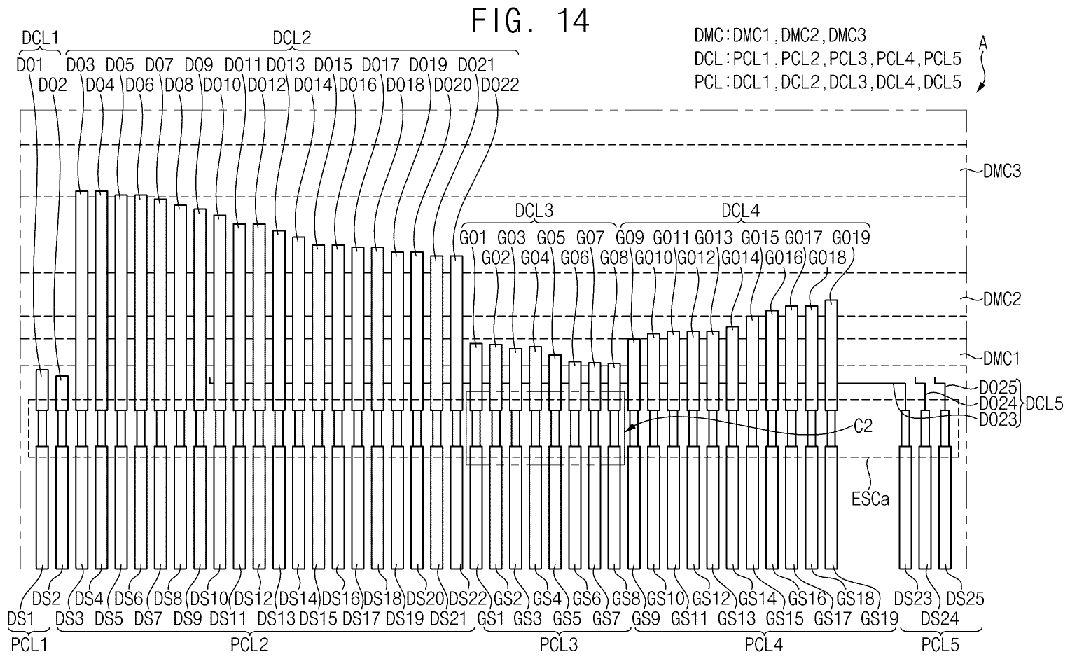

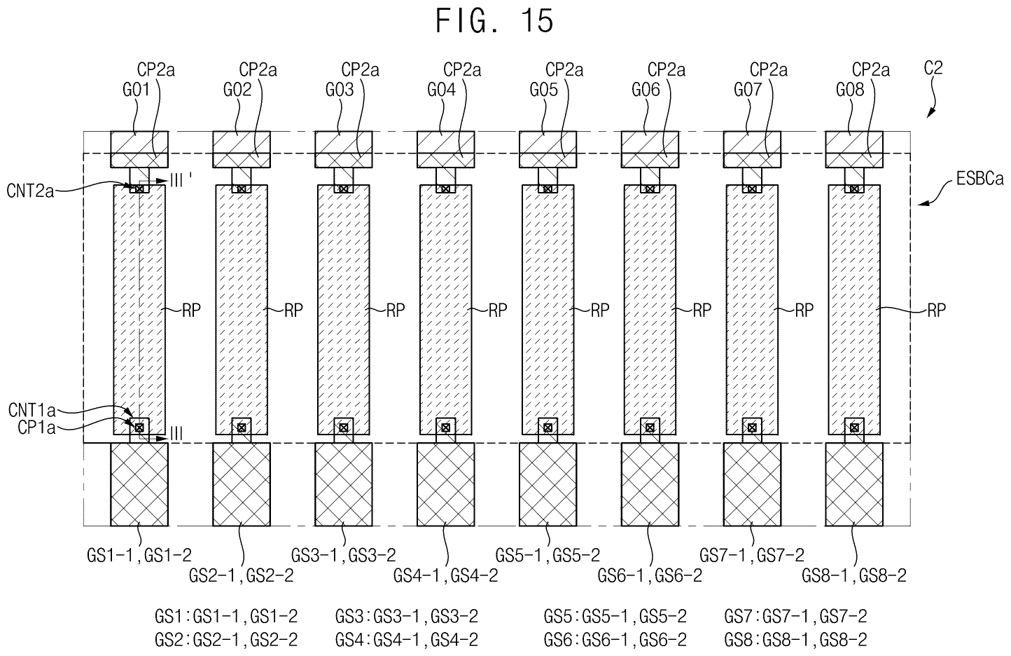

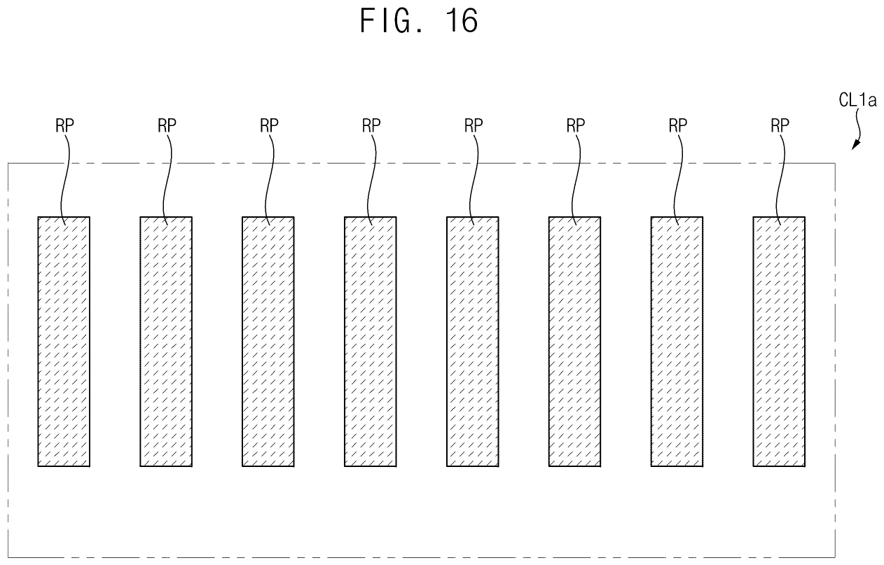

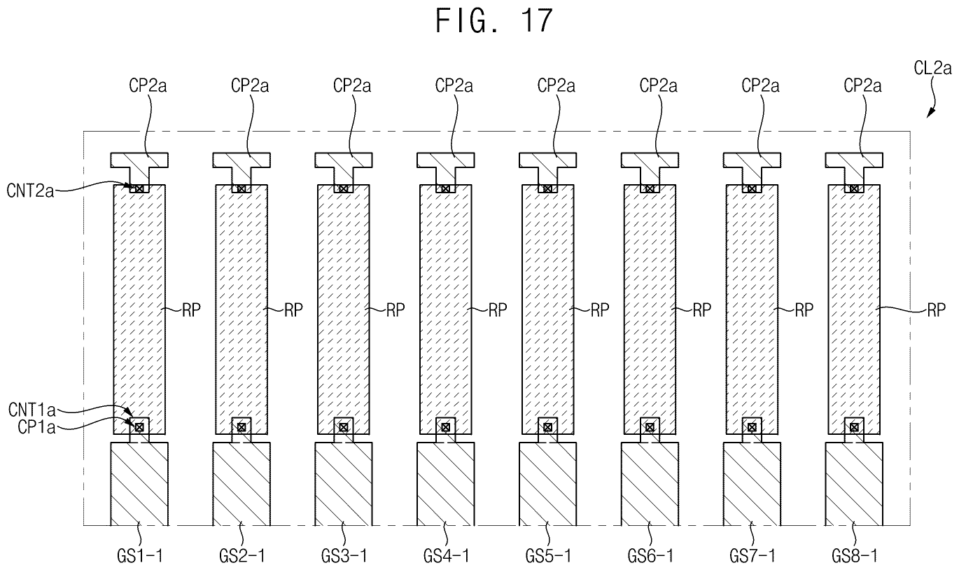

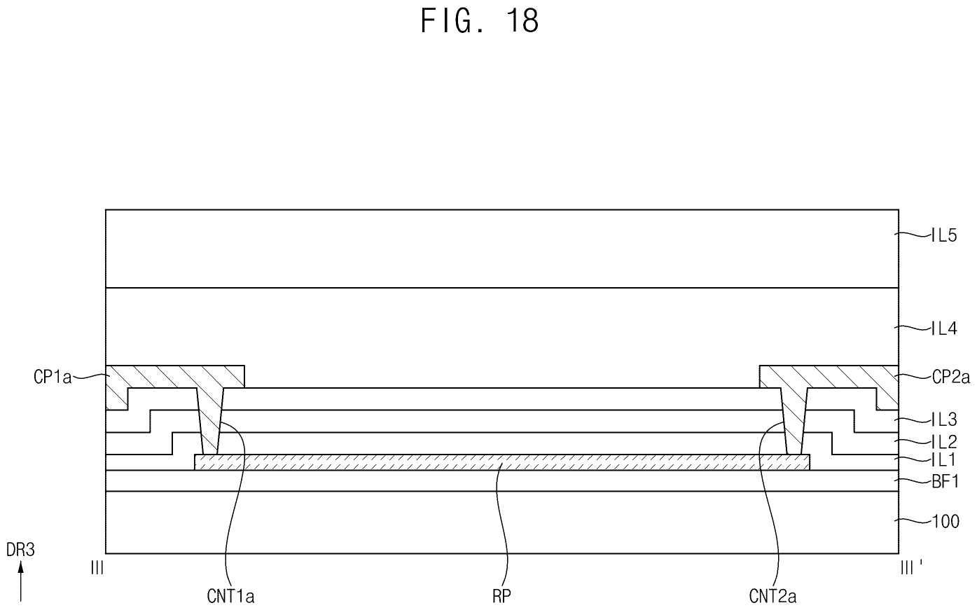

FIG. 14 is a plan view illustrating another enlarged example of the area A of FIG. 1. FIG. 15 is an enlarged plan view illustrating an area C2 of FIG. 14. FIGS. 16 and 17 are layout diagrams for explaining an arrangement of components included in an electrostatic discharge circuit of FIG. 15. FIG. 18 is a cross-sectional view illustrating a cross-section taken along the line III-III′ of FIG. 15.

The display device DD described with reference to FIGS. 14, 15, 16, 17, and 18 may be substantially a same as the display device DD described with reference to FIGS. 5, 6, 7, 8, 9, and 10, except for an electrostatic discharge circuit ESCa. Hereinafter, any content overlapping with the content described with reference to FIGS. 5, 6, 7, 8, 9, and 10 may be omitted or briefly described.

Referring to FIGS. 14, 15, 16, 17, and 18, the display panel (e.g., the display panel DP of FIG. 1) may include an electrostatic discharge circuit ESCa. The electrostatic discharge circuit ESCa may include a first conductive layer CL1a and a second conductive layer CL2a. For example, the first conductive layer CL1a and the second conductive layer CL2a may be sequentially laminated in the third direction DR3 on the substrate (e.g., the substrate SUB of FIG. 3).

The first conductive layer CL1a may include a plurality of resistance patterns RP. The second conductive layer CL2a may include a plurality of first connecting patterns CP1a and a plurality of second connecting patterns CP2a. In this specification, the plurality of first connecting patterns CP1a may be referred to as a plurality of connecting patterns.

Referring further to FIG. 3 and FIG. 4, the plurality of resistance patterns RP may be disposed in a same layer as the active layer ACT. For example, the plurality of resistance patterns RP may include a same material as the active layer ACT. For example, the plurality of resistance patterns RP may be formed through a same process as the active layer ACT.

In one or more embodiments, the plurality of resistance patterns RP may be arranged along the second direction DR2. In one or more embodiments, each of the plurality of resistance patterns RP may be spaced (e.g., spaced apart) from each other in a plan view. For example, each of the plurality of resistance patterns RP may be arranged along the second direction DR2 at a constant interval from each other. However, an arrangement of the plurality of resistance patterns RP according to one or more embodiments of the present disclosure may not be necessarily limited thereto.

In one or more embodiments, the lengths of each of the plurality of resistance patterns RP in the first direction DR1 in a plan view may be a same as each other. In one or more embodiments, a length of each of the plurality of resistance patterns RP in the second direction DR2 in a plan view may be a same as each other.

In one or more embodiments, a resistance of the plurality of resistance patterns RP may be about 10 kΩ to about 30 kΩ. Preferably, the resistance of the plurality of resistance patterns RP may be about 15 kΩ to about 25 kΩ. More preferably, the resistance of the plurality of resistance patterns RP may be about 20 kΩ.

In one or more embodiments, the plurality of first connecting patterns CP1a may be disposed in a same layer as the source electrode SE and the drain electrode DE. For example, the plurality of first connecting patterns CP1a may include a same material as the source electrode SE and the drain electrode DE. For example, the plurality of first connecting patterns CP1a may be formed through a same process as the source electrode SE and the drain electrode DE.

In one or more embodiments, the plurality of first connecting patterns CP1a may be arranged along the second direction DR2. In one or more embodiments, each of the plurality of first connecting patterns CP1a may be spaced (e.g., spaced apart) from each other in a plan view. For example, each of the plurality of first connecting patterns CP1a may be arranged along the second direction DR2 with a constant interval from each other. However, an arrangement of the plurality of first connecting patterns CP1a according to one or more embodiments of the present disclosure may not be necessarily limited thereto.

Each of the plurality of first connecting patterns CP1a may be electrically connected to each of the plurality of resistance patterns RP. For example, one first connecting pattern from among the plurality of first connecting patterns CP1a may contact one resistance pattern of the plurality of resistance patterns RP through a first contact hole CNT1a that penetrates the first insulating layer IL1, the second insulating layer IL2, and the third insulating layer IL3 in the thickness direction (e.g., the third direction DR3). In one or more embodiments, a plurality of first contact holes CNT1a may be arranged along the second direction DR2.

In one or more embodiments, the plurality of second connecting patterns CP2a may be disposed in a same layer as the source electrode SE and the drain electrode DE. For example, the plurality of second connecting patterns CP2a may include a same material as the source electrode SE and the drain electrode DE. For example, the plurality of second connecting patterns CP2a may be formed through a same process as the source electrode SE and the drain electrode DE.

In one or more embodiments, the plurality of second connecting patterns CP2a may be arranged along the second direction DR2. In one or more embodiments, each of the plurality of second connecting patterns CP2a may be spaced (e.g., spaced apart) from each other in a plan view. For example, each of the plurality of second connecting patterns CP2a may be arranged along the second direction DR2 with a constant interval from each other. However, an arrangement of the plurality of second connecting patterns CP2a according to embodiments of the present disclosure may not be necessarily limited to thereto.

Each of the plurality of second connecting patterns CP2a may be electrically connected to each of the plurality of resistance patterns RP. For example, one second connecting pattern of the plurality of second connecting patterns CP2a may contact one of the resistance patterns RP through a second contact hole CNT2a that penetrates the first insulating layer IL1, the second insulating layer IL2, and the third insulating layer IL3 in the thickness direction (e.g., the third direction DR3).

In one or more embodiments, a plurality of second contact holes CTN2a may be arranged along the second direction DR2. In one or more embodiments, the second contact hole CNT2a may be located in an opposite direction from the first contact hole CNT1a in the first direction DR1.

In one or more embodiments, one first connecting pattern from among the first connecting patterns CP1a and the first portion GS1-1 of the first gate signal line GS1 may be formed integrally. In one or more embodiments, one second connecting pattern among the second connecting patterns CP2a may overlap the first gate output signal line GO1 in a plan view.

In one or more embodiments, one first connecting pattern from among the first connecting patterns CP1a and the first portion GS2-1 of the second gate signal line GS2 may be formed integrally. In one or more embodiments, one second connecting pattern from among the second connecting patterns CP2a may overlap the second gate output signal line GO2 in a plan view.

In one or more embodiments, one first connecting pattern from among the first connecting patterns CP1a and the first portion GS3-1 of the third gate signal line GS3 may be formed integrally. In one or more embodiments, one second connecting pattern from among of the second connecting patterns CP2a may overlap the third gate output signal line GO3 in a plan view.

In one or more embodiments, one first connecting pattern from among the first connecting patterns CP1a and the first portion GS4-1 of the fourth gate signal line GS4 may be formed integrally. In one or more embodiments, one second connecting pattern from among the second connecting patterns CP2a may overlap the fourth gate output signal line GO4 in a plan view.

In one or more embodiments, one first connecting pattern from among the first connecting patterns CP1a and the first portion GS5-1 of the fifth gate signal line GS5 may be formed integrally. In one or more embodiments, one second connecting pattern from among the second connecting patterns CP2a may overlap the fifth gate output signal line GO5 in a plan view.

In one or more embodiments, the first connecting pattern of one of the first connecting patterns CP1a and the first portion GS6-1 of the sixth gate signal line GS6 may be formed integrally. In one or more embodiments, the second connecting pattern of one of the second connecting patterns CP2a may overlap the sixth gate output signal line GO6 in a plan view.

In one or more embodiments, one first connecting pattern from among the first connecting patterns CP1a and the first portion GS7-1 of the seventh gate signal line GS7 may be formed integrally. In one or more embodiments, one second connecting pattern from among the second connecting patterns CP2a may overlap the seventh gate output signal line GO7 in a plan view.

In one or more embodiments, one first connecting pattern from among the first connecting patterns CP1a and the first portion GS8-1 of the eighth gate signal line GS8 may be formed integrally. In one or more embodiments, one second connecting pattern from among the second connecting patterns CP2a may overlap the eighth gate output signal line GO8 in a plan view.

As described above, in the display device DD, the electrostatic discharge circuit ESCa may include a plurality of resistance patterns RP. Accordingly, when the touch panel TP is driven, static electricity flowing into the demultiplexer circuit DMC through the plurality of resistance patterns RP may be easily blocked, so that an electrostatic discharge phenomenon generated in the demultiplexer circuit DMC and a peripheral area of the demultiplexer circuit DMC may be prevented. Accordingly, a degradation phenomenon generated in transistors included in the demultiplexer circuit DMC (e.g., the first, second, and third demultiplexer transistors DMT1, DMT2, and DMT3 of FIGS. 11, 12, and 13) may be prevented. Accordingly, the touch function of the display device DD may be improved.

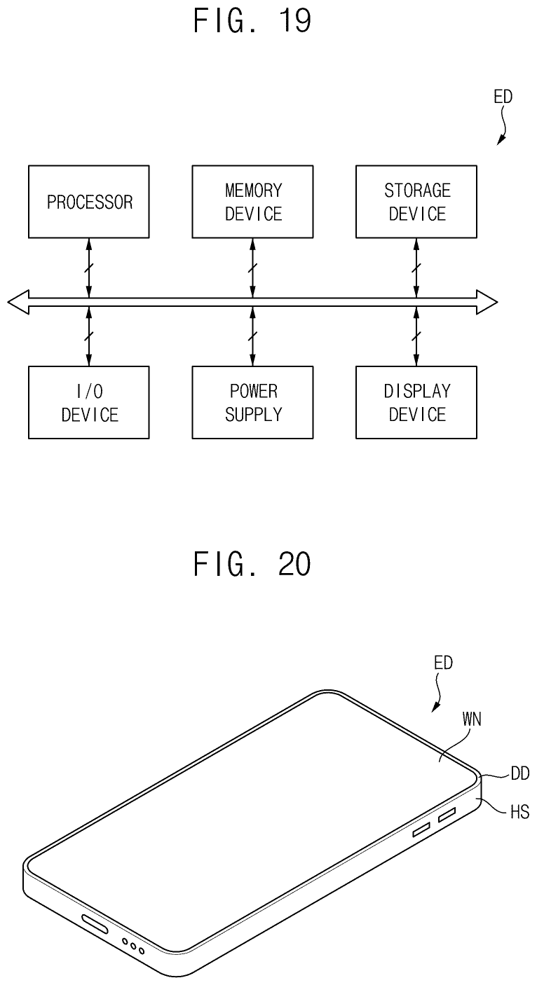

FIG. 19 is a block diagram illustrating an electronic device according to an embodiment of the present disclosure. FIG. 20 is a view illustrating an example of the electronic device of FIG. 19 implemented as a smartphone

Referring to FIGS. 19 and 20, an electronic device ED may include a processor, a memory device, a storage device, an input/output device, a power supply, and a display device. The display device included in the electronic device ED may be the display device DD of FIG. 1. In addition, the electronic device ED may further include several ports capable of communicating with a video card, a sound card, a memory card, a USB device, and/or the like., or communicating with other systems.

The processor may perform specific calculations or tasks. According to one or more embodiments, the processor may be a microprocessor, a central processing unit, an application processor, and/or the like. The processor may be connected to other components via an address bus, a control bus, a data bus, and/or the like. According to one or more embodiments, the processor may also be connected to an expansion bus such as a Peripheral Component Interconnect (PCI) bus. The processor may output data control signals and image data to a timing controller.

The memory device may store data required for the operation of the electronic device ED. For example, the memory device may include nonvolatile memory devices such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM), a ferroelectric random access memory (FRAM) device, and/or a volatile memory device such as a dynamic random access memory (DRAM) device, a static random access memory (SRAM) device, a mobile DRAM device, and/or the like.

The storage device may include a solid-state drive (SSD), a hard disk drive (HDD), a CD-ROM, and the like. The input/output device may include an input means such as a keyboard, a keypad, a touchpad, a touchscreen, a mouse, and/or the like., and an output means such as a speaker, a printer, and/or the like. According to one or more embodiments, the display device may be included in the input/output device. The power supply may supply power required for the operation of the electronic device ED. The display device may be connected to other components through the buses or other communication links.

In one or more embodiments, as illustrated in FIG. 20, the electronic device ED may be implemented as a smartphone. The electronic device ED may include a cover window WN, a display device DD, and a housing HS.

The cover window WN may cover the display device DD. For example, the cover window WN may be disposed in a display area (e.g., a display area DA of FIG. 1) of the display device DD to cover the display device DD. Accordingly, the cover window WN may protect the display area of the display device DD where the image is displayed.

The housing HS may surround the display device DD. For example, the display device DD may be accommodated in the housing HS. The housing HS may cover the side and bottom of the display device DD. Accordingly, the housing HS may supplement the rigidity of the display device DD and protect the display device DD from external impact.

A functional module such as a camera module or a sensor module may be accommodated inside the housing HS. Accordingly, the functional module may be electrically connected to the display device DD and perform a specific function. However, the type or arrangement of the functional module according to one or more embodiments of the present disclosure is not necessarily limited thereto.

However, this is an example, and the electronic device ED according to one or more embodiments of the present disclosure is not limited thereto. For example, the electronic device ED may be implemented as a mobile phone, a video phone, a smart pad, a smart watch, a tablet PC, a vehicle display, a computer monitor, a notebook computer, a head-mounted display device, and/or the like. In addition, the electronic device ED may be a television, a monitor, a notebook computer, and/or a tablet. In addition, the electronic device ED may be a car.

The devices according to one or more embodiments of the present disclosure may be applied to a device included in a computer, a notebook, a mobile phone, a smartphone, a smart pad, a PMP, a PDA, an MP3 player, and/or the like.

Although the devices according to one or more embodiments have been described with reference to the drawings, the illustrated embodiments are examples, and may be modified and changed by a person having ordinary knowledge in the relevant technical field without departing from the technical spirit described in the following claims.

What is claimed is:

1. A display device comprising:
a substrate including a display area in which at least one pixel is located, a non-display area adjacent to the display area, and a pad area spaced from one side of the display area;
a touch panel in the display area and the non-display area on the substrate;
a touch driving pad in the pad area on the substrate, and electrically connected to the touch panel;
a demultiplexer circuit in the pad area on the substrate, and located between the touch driving pad and the touch panel in a plan view;
a plurality of pad connecting lines on the substrate, and extending from the touch driving pad toward the demultiplexer circuit; and
an electrostatic discharge circuit between the plurality of pad connecting lines and the demultiplexer circuit in a plan view, the electrostatic discharge circuit comprising:
a plurality of electrostatic dissipation patterns spaced from each other in a plan view; and
an electrostatic capacitor electrode on the plurality of electrostatic dissipation patterns, and overlapping the plurality of electrostatic dissipation patterns in a plan view.

2. The display device of claim 1, wherein the electrostatic discharge circuit further comprises:
a plurality of connecting patterns on the electrostatic capacitor electrode, and electrically connected to the plurality of pad connecting lines.

3. The display device of claim 2, wherein each of the plurality of connecting patterns overlaps two electrostatic dissipation patterns adjacent to each of the plurality of connecting patterns from among the plurality of the electrostatic dissipation patterns.

4. The display device of claim 2, further comprising:
a first insulating structure between the plurality of electrostatic dissipation patterns and the electrostatic capacitor electrode in a cross-sectional view; and
a second insulating structure between the electrostatic capacitor electrode and the plurality of the connecting patterns in a cross-sectional view,
wherein the plurality of the connecting patterns is electrically connected to the plurality of electrostatic dissipation patterns through at least one contact hole penetrating the first insulating structure and the second insulating structure.

5. The display device of claim 4, wherein at least one hole exposes an upper surface of each of the plurality of electrostatic dissipation patterns.

6. The display device of claim 5, wherein a size of the hole is greater than a size of the contact hole.

7. The display device of claim 6, wherein the contact hole is inside the hole in a plan view.

8. The display device of claim 2, wherein the pixel comprises:
at least one transistor on the substrate; and
a light-emitting element electrically connected to the transistor and configured to emit light,
wherein the transistor comprises:
an active layer on the substrate;
a first gate electrode on the active layer;
a second gate electrode on the first gate electrode, and defining a capacitor with the first gate electrode; and
a source electrode and a drain electrode on the second gate electrode, and electrically connected to the active layer.

9. The display device of claim 8, wherein the plurality of the electrostatic dissipation patterns and the first gate electrode are in a same layer, and
wherein the electrostatic capacitor electrode and the second gate electrode are in a same layer.

10. The display device of claim 9, wherein the plurality of connecting patterns, the source electrode, and the drain electrode are in a same layer, and
wherein the plurality of pad connecting lines are on the plurality of connecting patterns.

11. The display device of claim 2, wherein each of the plurality of pad connecting lines extends a first direction,
wherein each of the plurality of electrostatic dissipation patterns is spaced from each other in a second direction crossing the first direction in a plan view, and
wherein the electrostatic capacitor electrode extends in the second direction, and overlaps each of the plurality of electrostatic dissipation patterns in a plan view.

12. The display device of claim 11, wherein a length of the electrostatic capacitor electrode in the first direction is greater than a length of the electrostatic capacitor electrode in the second direction.

13. The display device of claim 11, wherein a length of a portion of the electrostatic capacitor electrode overlapping one electrostatic dissipation pattern from among the plurality of the electrostatic dissipation patterns in the first direction is greater than a length of the portion of the electrostatic capacitor electrode overlapping one electrostatic dissipation pattern from among the plurality of the electrostatic dissipation patterns in the second direction.

14. The display device of claim 1, wherein the demultiplexer circuit comprises:
a first demultiplexer circuit adjacent to the electrostatic discharge circuit and comprising a plurality of first demultiplexer transistors;
a second demultiplexer circuit spaced from the first demultiplexer circuit in a plan view, and comprising a plurality of second demultiplexer transistors; and
a third demultiplexer circuit spaced from the second demultiplexer circuit, and comprising a plurality of third demultiplexer transistors.

15. The display device of claim 14, wherein a number of the plurality of the second demultiplexer transistors is greater than a number of the plurality of the first demultiplexer transistors, and
wherein a number of the plurality of the third demultiplexer transistors is greater than a number of the plurality of the first demultiplexer transistors.

16. A display device comprising:
a substrate including a display area in which at least one pixel is located, a non-display area adjacent to the display area, and a pad area spaced from one side of the display area;
a touch panel in the display area and the non-display area on the substrate;
a touch driving pad in the pad area on the substrate, and electrically connected to the touch panel;
a demultiplexer circuit in the pad area on the substrate, located between the touch driving pad and the touch panel in a plan view, and comprising a first demultiplexer circuit, a second demultiplexer circuit, and a third demultiplexer circuit that are spaced from each other;
a plurality of pad connecting lines on the substrate, and extending from the touch driving pad toward the demultiplexer circuit; and
an electrostatic discharge circuit comprising a plurality of resistance patterns located between the plurality of pad connecting lines and the demultiplexer circuit in a plan view, and spaced from each other.

17. The display device of claim 16, wherein the pixel comprises:
at least one transistor on the substrate; and
a light-emitting element electrically connected to the transistor and configured to emit light,
wherein the transistor comprises:
an active layer on the substrate;
a first gate electrode on the active layer;
a second gate electrode on the first gate electrode, and defining a capacitor with the first gate electrode; and
a source electrode and a drain electrode on the second gate electrode, and electrically connected to the active layer.

18. The display device of claim 17, wherein the electrostatic discharge circuit further comprises:
a plurality of connecting patterns electrically connected to the plurality of pad connecting lines,
wherein the plurality of resistance patterns and the active layer are in a same layer,
wherein the plurality of connecting patterns, the source electrode, and the drain electrode are in a same layer, and
wherein the plurality of the pad connecting patterns are on the plurality of connecting patterns.

19. The display device of claim 16, wherein a resistance of the plurality of resistance patterns is about 15 kΩ to about 25 kΩ.

20. An electronic device comprising:
a housing
a display device housed in the housing, configured to display an image, and comprising:
a substrate including a display area in which at least one pixel is located, a non-display area adjacent to the display area, and a pad area spaced from one side of the display area;
a touch panel in the display area and the non-display area on the substrate;
a touch driving pad in the pad area on the substrate, and electrically connected to the touch panel;
a demultiplexer circuit in the pad area on the substrate, and located between the touch driving pad and the touch panel in a plan view;
a plurality of pad connecting lines on the substrate, and extending from the touch driving pad toward the demultiplexer circuit; and
an electrostatic discharge circuit between the plurality of pad connecting lines and the demultiplexer circuit in a plan view, the electrostatic discharge circuit comprising:
a plurality of electrostatic dissipation patterns spaced from each other in a plan view; and
an electrostatic capacitor electrode on the plurality of electrostatic dissipation patterns, and overlapping the plurality of electrostatic dissipation patterns in a plan view; and
a cover window covering the display device.
